(19) United States
(12) Patent Application Publication
(10) Pub. No.: US 2024/0175906 A1
(43) Pub. Date: May 30, 2024

(54) REAL-TIME ELECTRIC VEHICLE CHARGING DETECTION

(71) Applicant: Utilidata, Inc., Providence, RI (US)

(72) Inventors: Qiuhua Huang, Littleton, CO (US); Taylor Spalt, Richmond, VA (US)

(73) Assignee: Utilidata, Inc., Providence, RI (US)

(21) Appl. No.: 18/223,756

(22) Filed: Jul. 19, 2023

Related U.S. Application Data
(60) Provisional application No. 63/428,475, filed on Nov. 29, 2022.
(60) Provisional application No. 63/433,593, filed on Dec. 19, 2022.
(60) Provisional application No. 63/453,286, filed on Mar. 20, 2023.

(51) Int. Cl. G01R 22/10; G06N 20/10

(52) U.S. Cl. CPC G01R 22/10; G06N 20/10

(57) ABSTRACT

Systems and methods for real-time (EV) charging detection. The system can include a metering system. The metering system can detect, via a sensor, current associated with electricity consumed in the utility grid during a first time interval. The metering system can determine a current harmonic metric and a power metric associated with the electricity delivered over the utility grid in the first time interval. The metering system can input the current harmonic metric and the power metric into a model trained with machine learning and deployed on the metering system to determine a likelihood that at least a portion of the electricity delivered over the utility grid in the first time interval is used to charge an electric vehicle. The metering system can execute an action associated with performance of the utility grid responsive to the likelihood satisfying a threshold.

### CROSS-REFERENCES TO RELATED APPLICATIONS

This application claims the benefit of priority under 35 U.S.C. § 119 to U.S. Provisional Patent Application No. 63/428,475, filed Nov. 29, 2022, U.S. Provisional Patent Application No. 63/433,593, filed Dec. 19, 2022, and U.S. Provisional Patent Application No. 63/453,286, filed Mar. 20, 2023, each of which is hereby incorporated by reference herein in its entirety.

### FIELD OF THE DISCLOSURE

This disclosure relates generally to systems and methods for real-time detection of electric vehicle (EV) charging according to high-resolution transient data and edge computing.

### BACKGROUND

Utility distribution grids can generate and distribute electric power to various grid edges (e.g., edge devices or electric consumption entities). The utility distribution grids can supply power via transmission or distribution lines to various loads at the grid edges, such as consumer electric devices or residential charging infrastructures. The utility distribution grids can use meters to observe or measure utility delivery or consumption in the grid.

### BRIEF SUMMARY OF THE DISCLOSURE

Within the utility distribution grids, charging infrastructures can be installed at residential or consumer sites, including charging stations for charging electric vehicles (EVs). As the number of EVs increases, the scale of the charging infrastructures may also increase, potentially resulting in large-scale residential EV charging. The large-scale (or increase in) residential EV charging can burden or result in excessive load on the utility grid, affecting the planning or operations of the utility grid when the charging is not orchestrated (e.g., the time, duration, amplitude, or other variables are not scheduled or identified). Because EVs carry large batteries (e.g., 20 to 100 kWh capacity, among other capacities), these batteries may be used as mobile energy storage to support edge devices (e.g., electric devices at the consumer site) or the utility grid, potentially reducing loads on the utility grid or providing power to other edge devices, such as during power disruption events. The ability to detect EV charging can enable or allow for the determination of charging characteristics, the estimation of the EV penetration or growth rates within the utility grid distribution range, or the determination of the effects of EVs (e.g., EV charging) on the power quality at the grid edge. For proper operation of the utility grid, such as preparing, managing, or leveraging the EVs as contributing assets to functionalities of the grid (e.g., supplying electricity from the battery of the EVs to the edge devices), the components of the utility grid can utilize the capabilities associated with detecting EV charging events to determine charging behaviors, effects of the charging events on the system (e.g., utility grid), or growth trajectory of EV charging. However, it can be challenging to detect EV charging in residential areas due to aggregated or mixed signals from the charging infrastructures and other consumer electric devices (e.g., other residential loads), which may be sampled at a relatively low time resolution in certain systems. This technical solution can utilize computing resources at the edge and communications to remote computing devices (e.g., the cloud) to provide a more effective, reliable, and accurate approach to addressing the challenges in detecting EV charging events.

In some cases, the EV charging detection may be performed offline or in batch mode after collecting power measurements from a number of charging events. The outcome of the detection may not be applied to (e.g., near) real-time energy management and control applications, such as high-frequency control or power balancing. Some systems can obtain smart meter measurements which can be uploaded to the cloud environment for analysis (e.g., in an attempt to detect EV charging), with a time delay from minutes to hours, for example. However, the extent of the time delay resulting from uploading to the cloud environment (e.g., also from receiving a response from the cloud environment) may not be desired, for instance, to accomplish the aforementioned grid services or controls.

In some cases, the harmonic emission generated by EV charging events may not be leveraged. For instance, harmonics may not be recorded or collected due to the lack of compatibility or support (e.g., limited computing power or bandwidth constraints when communicating with the cloud environment).

Therefore, the systems and methods of the technical solution discussed herein can provide metering devices configured to perform real-time charging detection to maximize the ability to manage or support EV charging via utility control or aggregators (e.g., virtual power plants). The systems and methods can include real-time energy/power management and control applications to provide relatively high-frequency control or power balancing. The systems and methods can utilize harmonic emission generated by the charging infrastructures (e.g., before, during, or after EV charging), for instance, to detect power consumption ramp-up or ramp-down. Utilizing the detectable harmonics can enable the distinction between the power or energy consumed by an EV charger from other residential loads. The systems and methods can leverage relatively high-resolution data (e.g., at least 10 kHz sampling rate) recorded locally relative to the EV charging location (e.g., recorded by the metering device associated with the respective charging units). The metering devices can be configured with the necessary computing power to execute the various operations or computations, and the necessary network bandwidth for data transmission to at least one remote computing device (e.g., cloud).

This disclosure is directed to a system for real-time detection of electric vehicle (EV) charging. The system can include a metering system, comprising one or more processors and memory, located on a utility grid downstream from a substation. The metering system can detect, via a sensor of the metering system, current associated with electricity consumed in the utility grid during a first time interval. The metering system can determine, based on the current detected by the sensor, a current harmonic metric and a power metric associated with the electricity delivered over the utility grid in the first time interval. The metering system can input the current harmonic metric and the power metric into a model trained with machine learning and deployed on the metering system to determine a likelihood that at least a portion of the electricity delivered over the utility grid in the first time interval is used to charge an electric vehicle. The metering system can execute an action associated with performance of the utility grid responsive to the likelihood satisfying a threshold.

The metering system can receive, via a network, the model from a data processing system remote from the metering system, wherein the data processing system trains the model via machine learning. The model can be trained with first training data sampled at a first resolution and second training data sampled at a second resolution that is greater than the first resolution. The model can be trained with first training data comprising historical load metrics for a plurality of time stamps. Each of the plurality of time stamps may be assigned one of a first label that indicates electric vehicle charging or a second label that indicates no electric vehicle charging during the corresponding plurality of time stamps.

Training data used to train the model can be filtered based on a comparison of an output of a support vector machine trained to classify a harmonics and power data set as corresponding to electric vehicle charging or no electric vehicle charging with a second threshold. The model can comprise a convolution neural network long short-term memory network.

The system can include a data processing system comprising one or more processors coupled with memory. The data processing system can receive time-series data sampled at a first resolution corresponding to residential electric load. The data processing system can detect, based on a second threshold, one or more time intervals of electric vehicle charging in the time-series data. The data processing system can label, based on the detection, the time-series data to indicate the one or more time intervals of electric vehicle charging to generate labeled time-series data. The data processing system can receive a harmonics and power data set sampled at a second resolution greater than the first resolution. The data processing system can input the labeled time-series data and the harmonics and power data set into a support vector machine to train the support vector machine to classify the harmonics and power data set to indicate electric vehicle charging or no electric vehicle charging. The data processing system can use the trained support vector machine to filter a second harmonics and power data set to generate a filtered second harmonics and power data set. The data processing system can train, via a convolution neural network long short-term memory network, the model with the filtered second harmonics and power data set.

The first resolution can correspond to 1 Hz. The second resolution can correspond to 10 kHz. The current detected by the sensor of the metering system can be sampled at 10 kHz. The metering system can receive, via a network, an update to the model from a data processing system that re-trains the model based on additional data to generate the update to the model. The metering system, to execute the action, can provide an alert to a data processing system indicating electric vehicle charging in the first time interval.

In another aspect, this disclosure is directed to a method for real-time detection of EV charging. The method can include detecting, by a metering system comprising one or more processors and memory located on a utility grid downstream from a substation, via a sensor of the metering system, current associated with electricity consumed in the utility grid during a first time interval. The method can include determining, by the metering system, based on the current detected by the sensor, a current harmonic metric and a power metric associated with the electricity delivered over the utility grid in the first time interval. The method can include inputting, by the metering system, the current harmonic metric and the power metric into a model trained with machine learning and deployed on the metering system to determine a likelihood that at least a portion of the electricity delivered over the utility grid in the first time interval is used to charge an electric vehicle. The method can include executing, by the metering system, an action associated with performance of the utility grid responsive to the likelihood satisfying a threshold.

The method can include receiving, by the metering system via a network, the model from a data processing system remote from the metering system, wherein the data processing system trains the model via machine learning. The model can be trained with first training data sampled at a first resolution and second training data sampled at a second resolution that is greater than the first resolution.

The model can be trained with first training data comprising historical load metrics for a plurality of time stamps. Each of the plurality of time stamps may be assigned one of a first label that indicates electric vehicle charging or a second label that indicates no electric vehicle charging during the corresponding plurality of time stamps.

Training data used to train the model may be filtered based on a comparison of an output of a support vector machine trained to classify a harmonics and power data set as corresponding to electric vehicle charging or no electric vehicle charging with a second threshold. The model can comprise a convolution neural network long short-term memory network.

The method can include receiving, by a data processing system comprising one or more processors coupled with memory, time-series data sampled at a first resolution corresponding to residential electric load. The method can include detecting, by the data processing system based on a second threshold, one or more time intervals of electric vehicle charging in the time-series data. The method can include labeling, by the data processing system based on the detection, the time-series data to indicate the one or more time intervals of electric vehicle charging to generate labeled time-series data. The method can include receiving, by the data processing system, a harmonics and power data set sampled at a second resolution greater than the first resolution. The method can include inputting, by the data processing system, the labeled time-series data and the harmonics and power data set into a support vector machine to train the support vector machine to classify the harmonics and power data set to indicate electric vehicle charging or no electric vehicle charging. The method can include using, by the data processing system, the trained support vector machine to filter a second harmonics and power data set to generate a filtered second harmonics and power data set. The method can include training, by the data processing system via a convolution neural network long short-term memory network, the model with the filtered second harmonics and power data set.

The method can include receiving, by the metering system via a network, an update to the model from a data processing system that re-trains the model based on additional data to generate the update to the model. The method can include executing, by the metering system, the action to provide an alert to a data processing system indicating electric vehicle charging in the first time interval.

In yet another aspect, this disclosure is directed to a non-transitory computer-readable medium for real-time detection of EV charging. The non-transitory computer-readable medium can store processor-executable instructions that, when executed by one or more processors, cause the one or more processors to detect, via a sensor of a metering system, current associated with electricity consumed in a utility grid during a first time interval; determine, based on the current detected by the sensor, a current harmonic metric and a power metric associated with the electricity delivered over the utility grid in the first time interval; input the current harmonic metric and the power metric into a model trained with machine learning and deployed on the metering system to determine a likelihood that at least a portion of the electricity delivered over the utility grid in the first time interval is used to charge an electric vehicle; and execute an action associated with performance of the utility grid responsive to the likelihood satisfying a threshold.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification.

### BRIEF DESCRIPTION OF THE FIGURES

The accompanying drawings are not intended to be drawn to scale. Like reference numbers and designations in the various drawings indicate like elements having similar structure or functionality. For purposes of clarity, not every component may be labeled in every drawing. In the drawings:

FIG. 1 is a block diagram depicting an illustrative utility grid, in accordance with an implementation;

FIG. 2 is a block diagram illustrating an example system for real-time detection of EV charging, in accordance with an implementation;

FIG. 3 is a flow diagram of an example overview for model generation and deployment, in accordance with an implementation;

FIGS. 4A-4F illustrate a flow diagram of an example method for offline charging detection and associated graphs, in accordance with an implementation;

FIG. 5 is an illustration of an example harmonics and power dataset used as input into a model, in accordance with an implementation;

FIG. 6 is a flow diagram of an example method for real-time detection of EV charging, in accordance with an implementation; and

FIG. 7 is a block diagram illustrating an architecture for a computer system that can be employed to implement elements of the systems and methods described and illustrated herein, including, for example, aspects of the utility grid depicted in FIG. 1.

The features and advantages of the present solution will become more apparent from the detailed description set forth below when taken in conjunction with the drawings, in which like reference characters identify corresponding elements throughout. Other features, aspects, and advantages of the subject matter will become apparent from the description, the drawings, and the claims.

### DETAILED DESCRIPTION

Following below are more detailed descriptions of various concepts related to, and implementations of, methods, apparatuses, and systems of real-time detection of electric vehicle (EV) charging. The various concepts introduced above and discussed in greater detail below may be implemented in any of numerous ways.

The systems and methods of the technical solution discussed herein can detect charging events to manage the charging of EVs or other machines or devices using the charging infrastructures. The systems and methods can include real-time energy/power management and control applications to provide relatively high-frequency control or power balancing. The systems and methods can utilize harmonic emission generated by the charger, for instance, to detect power consumption ramp-up or ramp-down (e.g., increase or decrease in power consumption). The systems and methods can leverage relatively high-resolution data (e.g., at least 10 kHz sampling rate) recorded locally relative to the EV charging location (e.g., recorded by the metering device associated with the respective charging units). The features or operations can be executed on the metering device or a remote computing device, such as a computing or data processing device external to or at a location remote from the metering device.

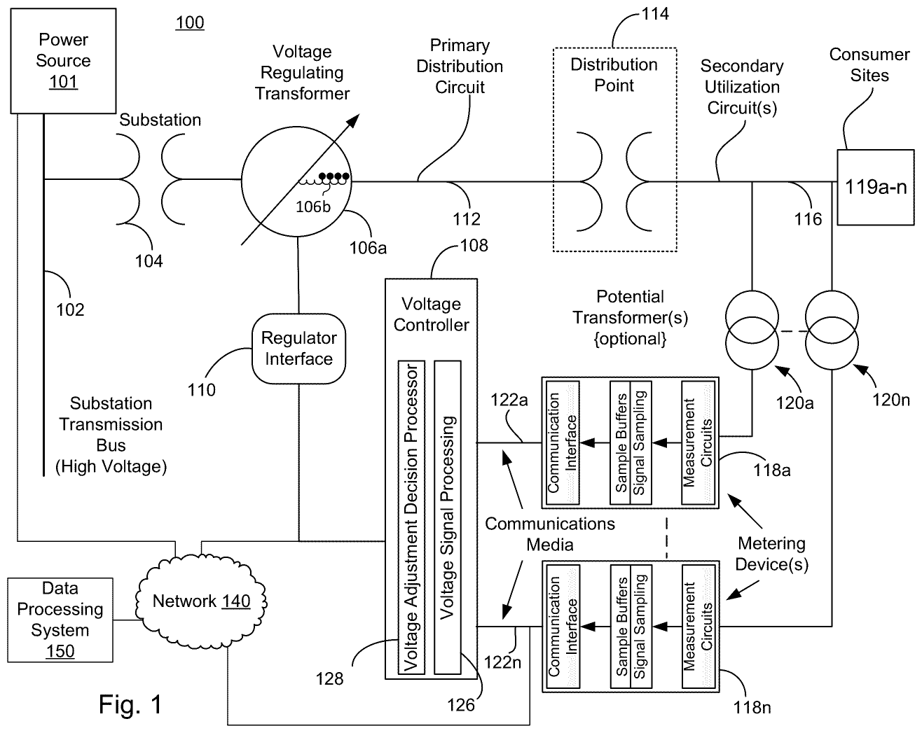

FIG. 1 depicts an example utility distribution environment. The utility distribution environment can include a utility grid 100. The utility grid 100 can include an electricity distribution grid with one or more devices, assets, or digital computational devices and systems, such as a data processing system 150. In brief overview, the utility grid 100 includes a power source 101 that can be connected via a subsystem transmission bus 102 and/or via substation transformer 104 to a voltage regulating transformer 106a. The voltage regulating transformer 106a can be controlled by voltage controller 108 with regulator interface 110. Voltage regulating transformer 106a can be optionally coupled on primary distribution circuit 112 via optional distribution transformer 114 to secondary utilization circuits 116 and to one or more electrical or electronic devices 119. Voltage regulating transformer 106a can include multiple tap outputs 106b with each tap output 106b supplying electricity with a different voltage level. The utility grid 100 can include monitoring devices 118a-118n that can be coupled through optional potential transformers 120a-120n to secondary utilization circuits 116. The monitoring or metering devices 118a-118n can detect (e.g., continuously, periodically, based on a time interval, responsive to an event or trigger) measurements and continuous voltage signals of electricity supplied to one or more electrical devices 119 connected to circuit 112 or 116 from a power source 101 coupled to bus 102. These metering devices 118a-118n, among other components within utility distribution grids, can collect samples of power delivery or consumption, such as voltage information, at a predetermined sample rate. A voltage controller 108 can receive, via a communication media 122, measurements obtained by the metering devices 118a-118n, and use the measurements to make a determination regarding a voltage tap settings, and provide an indication to regulator interface 110. The regulator interface can communicate with voltage regulating transformer 106a to adjust an output tap level 106b.

In FIG. 1, in further detail, the utility grid 100 includes a power source 101. The power source 101 can include a power plant such as an installation configured to generate electrical power for distribution. The power source 101 can include an engine or other apparatus that generates electrical power. The power source 101 can create electrical power by converting power or energy from one state to another state. In some embodiments, the power source 101 can be referred to or include a power plant, power station, generating station, powerhouse or generating plant. In some embodiments, the power source 101 can include a generator, such as a rotating machine that converts mechanical power into electrical power by creating relative motion between a magnetic field and a conductor. The power source 101 can use one or more energy source to turn the generator including, e.g., fossil fuels such as coal, oil, and natural gas, nuclear power, or cleaner renewable sources such as solar, wind, wave and hydroelectric.

In some embodiments, the utility grid 100 includes one or more substation transmission bus 102. The substation transmission bus 102 can include or refer to transmission tower, such as a structure (e.g., a steel lattice tower, concrete, wood, etc.), that supports an overhead power line used to distribute electricity from a power source 101 to a substation 104 or distribution point 114. Transmission towers 102 can be used in high-voltage AC and DC systems, and come in a wide variety of shapes and sizes. In an illustrative example, a transmission tower can range in height from 15 to 55 meters or more. Transmission towers 102 can be of various types including, e.g., suspension, terminal, tension, and transposition. In some embodiments, the utility grid 100 can include underground power lines in addition to or instead of transmission towers 102.

In some embodiments, the utility grid 100 includes a substation 104 or electrical substation 104 or substation transformer 104. A substation can be part of an electrical generation, transmission, and distribution system. In some embodiments, the substation 104 transform voltage from high to low, or the reverse, or performs any of several other functions to facilitate the distribution of electricity. In some embodiments, the utility grid 100 can include several substations 104 between the power plant 101 and the consumer electoral devices 119 with electric power flowing through them at different voltage levels.

The substations 104 can be remotely operated, supervised and controlled (e.g., via a supervisory control and data acquisition system or data processing system 150). A substation can include one or more transformers to change voltage levels between high transmission voltages and lower distribution voltages, or at the interconnection of two different transmission voltages.

The regulating transformer 106 can include: (1) a multi-tap autotransformer (single or three phase), which are used for distribution; or (2) on-load tap changer (three phase transformer), which can be integrated into a substation transformer 104 and used for both transmission and distribution. The illustrated system described herein can be implemented as either a single-phase or three-phase distribution system. The utility grid 100 can include an alternating current (AC) power distribution system and the term voltage can refer to an “RMS Voltage”, in some embodiments.

The utility grid 100 can include a distribution point 114 or distribution transformer 114, which can refer to an electric power distribution system. In some embodiments, the distribution point 114 can be a final or near final stage in the delivery of electric power. For example, the distribution point 114 can carry electricity from the transmission system (which can include one or more transmission towers 102) to individual consumers 119. In some embodiments, the distribution system can include the substations 104 and connect to the transmission system to lower the transmission voltage to medium voltage ranging between 2 kV and 35 kV with the use of transformers, for example. Primary distribution lines or circuit 112 carry this medium voltage power to distribution transformers located near the customer's premises 119. Distribution transformers can further lower the voltage to the utilization voltage of appliances and can feed several customers 119 through secondary distribution lines or circuits 116 at this voltage. Commercial and residential customers 119 can be connected to the secondary distribution lines through service drops. In some embodiments, customers demanding high load can be connected directly at the primary distribution level or the sub-transmission level.

The utility grid 100 can include or couple to one or more consumer sites 119. Consumer sites 119 can include, for example, a building, house, shopping mall, factory, office building, residential building, commercial building, stadium, movie theater, etc. The consumer sites 119 can be configured to receive electricity from the distribution point 114 via a power line (above ground or underground). A consumer site 119 can be coupled to the distribution point 114 via a power line. The consumer site 119 can be further coupled to a site meter 118a-n or advanced metering infrastructure (“AMI”). The site meter 118a-n can be associated with a controllable primary circuit segment 112. The association can be stored as a pointer, link, field, data record, or other indicator in a data file in a database.

The utility grid 100 can include site meters 118a-n or AMI. Site meters 118a-n can measure, collect, and analyze energy usage, and communicate with metering devices such as electricity meters, gas meters, heat meters, and water meters, either on request or on a schedule. Site meters 118a-n can include hardware, software, communications, consumer energy displays and controllers, customer associated systems, Meter Data Management (MDM) software, or supplier business systems. In some embodiments, the site meters 118a-n can obtain samples of electricity usage in real time or based on a time interval, and convey, transmit or otherwise provide the information. In some embodiments, the information collected by the site meter can be referred to as meter observations or metering observations and can include the samples of electricity usage. In some embodiments, the site meter 118a-n can convey the metering observations along with additional information such as a unique identifier of the site meter 118a-n, unique identifier of the consumer, a time stamp, date stamp, temperature reading, humidity reading, ambient temperature reading, etc. In some embodiments, each consumer site 119 (or electronic device) can include or be coupled to a corresponding site meter or monitoring device 118a-118n.

Monitoring devices 118a-118n can be coupled through communications media 122a-122n to voltage controller 108. Voltage controller 108 can compute (e.g., discrete-time, continuously or based on a time interval or responsive to a condition/event) values for electricity that facilitates regulating or controlling electricity supplied or provided via the utility grid. For example, the voltage controller 108 can compute estimated deviant voltage levels that the supplied electricity (e.g., supplied from power source 101) will not drop below or exceed as a result of varying electrical consumption by the one or more electrical devices 119. The deviant voltage levels can be computed based on a predetermined confidence level and the detected measurements. Voltage controller 108 can include a voltage signal processing circuit 126 that receives sampled signals from metering devices 118a-118n. Metering devices 118a-118n can process and sample the voltage signals such that the sampled voltage signals are sampled as a time series (e.g., uniform time series free of spectral aliases or non-uniform time series).

Voltage signal processing circuit 126 can receive signals via communications media 122a-n from metering devices 118a-n, process the signals, and feed them to voltage adjustment decision processor circuit 128. Although the term “circuit” is used in this description, the term is not meant to limit this disclosure to a particular type of hardware or design, and other terms known generally known such as the term “element”, “hardware”, “device” or “apparatus” could be used synonymously with or in place of term “circuit” and can perform the same function. For example, in some embodiments the functionality can be carried out using one or more digital processors, e.g., implementing one or more digital signal processing algorithms. Adjustment decision processor circuit 128 can determine a voltage location with respect to a defined decision boundary and set the tap position and settings in response to the determined location. For example, the adjustment decision processing circuit 128 in voltage controller 108 can compute a deviant voltage level that is used to adjust the voltage level output of electricity supplied to the electrical device. Thus, one of the multiple tap settings of regulating transformer 106 can be continuously selected by voltage controller 108 via regulator interface 110 to supply electricity to the one or more electrical devices based on the computed deviant voltage level. The voltage controller 108 can also receive information about voltage regulator transformer 106a or output tap settings 106b via the regulator interface 110. Regulator interface 110 can include a processor controlled circuit for selecting one of the multiple tap settings in voltage regulating transformer 106 in response to an indication signal from voltage controller 108. As the computed deviant voltage level changes, other tap settings 106b (or settings) of regulating transformer 106a are selected by voltage controller 108 to change the voltage level of the electricity supplied to the one or more electrical devices 119.

The network 140 can be connected via wired or wireless links. Wired links can include Digital Subscriber Line (DSL), coaxial cable lines, or optical fiber lines. The wireless links can include BLUETOOTH, Wi-Fi, Worldwide Interoperability for Microwave Access (WiMAX), an infrared channel or satellite band. The wireless links can also include any cellular network standards used to communicate among mobile devices, including standards that qualify as 1G, 2G, 3G, or 4G. The network standards can qualify as one or more generation of mobile telecommunication standards by fulfilling a specification or standards such as the specifications maintained by International Telecommunication Union. The 3G standards, for example, can correspond to the International Mobile Telecommunications-2000 (IMT-2000) specification, and the 4G standards can correspond to the International Mobile Telecommunications Advanced (IMT-Advanced) specification. Examples of cellular network standards include AMPS, GSM, GPRS, UMTS, LTE, LTE Advanced, Mobile WiMAX, and WiMAX-Advanced. Cellular network standards can use various channel access methods e.g. FDMA, TDMA, CDMA, or SDMA. In some embodiments, different types of data can be transmitted via different links and standards. In other embodiments, the same types of data can be transmitted via different links and standards.

The network 140 can be any type and/or form of network. The geographical scope of the network 140 can vary widely and the network 140 can be a body area network (BAN), a personal area network (PAN), a local-area network (LAN), e.g. Intranet, a metropolitan area network (MAN), a wide area network (WAN), or the Internet. The topology of the network 140 can be of any form and can include, e.g., any of the following: point-to-point, bus, star, ring, mesh, or tree. The network 140 can be an overlay network which is virtual and sits on top of one or more layers of other networks 140. The network 140 can be of any such network topology as known to those ordinarily skilled in the art capable of supporting the operations described herein. The network 140 can utilize different techniques and layers or stacks of protocols, including, e.g., the Ethernet protocol, the internet protocol suite (TCP/IP), the ATM (Asynchronous Transfer Mode) technique, the SONET (Synchronous Optical Networking) protocol, or the SDH (Synchronous Digital Hierarchy) protocol. The TCP/IP internet protocol suite can include application layer, transport layer, internet layer (including, e.g., IPv6), or the link layer. The network 140 can be a type of a broadcast network, a telecommunications network, a data communication network, or a computer network.

The network 140 can include computer networks such as the internet, local, wide, near field communication, metro or other area networks, as well as satellite networks or other computer networks such as voice or data mobile phone communications networks, and combinations thereof. The network 140 can include a point-to-point network, broadcast network, telecommunications network, asynchronous transfer mode network, synchronous optical network, or a synchronous digital hierarchy network, for example. The network 140 can include at least one wireless link such as an infrared channel or satellite band. The topology of the network 140 can include a bus, star, or ring network topology. The network 140 can include mobile telephone or data networks using any protocol or protocols to communicate among vehicles or other devices, including advanced mobile protocols, time or code division multiple access protocols, global system for mobile communication protocols, general packet radio services protocols, or universal mobile telecommunication system protocols, and the same types of data can be transmitted via different protocols.

One or more components, assets, or devices of utility grid 100 can communicate via network 140. The utility grid 100 can use one or more networks, such as public or private networks. The utility grid 100 can communicate or interface with a data processing system 150 designed and constructed to communicate, interface or control the utility grid 100 via network 140. Each asset, device, or component of utility grid 100 can include one or more computing devices 700 or a portion of computing device 700 or some or all functionality of computing device 700.

The data processing system 150 can reside on a computing device of the utility grid 100, or on a computing device or server external from, or remote from the utility grid 100. The data processing system 150 can reside or execute in a cloud computing environment or distributed computing environment. The data processing system 150 can reside on or execute on multiple local computing devices located throughout the utility grid 100. For example, the utility grid 100 can include multiple local computing devices each configured with one or more components or functionality of the data processing system 150.

Each of the components of the data processing system 150 can be implemented using hardware or a combination of software and hardware. Each component of the data processing system 150 can include logical circuitry (e.g., a central processing unit or CPU) that responses to and processes instructions fetched from a memory unit (e.g., memory 715 or storage device 725). Each component of the data processing system 150 can include or use a microprocessor or a multi-core processor. A multi-core processor can include two or more processing units on a single computing component. Each component of the data processing system 150 can be based on any of these processors, or any other processor capable of operating as described herein. Each processor can utilize instruction level parallelism, thread level parallelism, different levels of cache, etc. For example, the data processing system 150 can include at least one logic device such as a computing device or server having at least one processor to communicate via the network 140.

The components and elements of the data processing system 150 can be separate components, a single component, or part of the data processing system 150. For example, individual components or elements of the data processing system 150 can operate concurrently to perform at least one feature or function discussed herein. In another example, components of the data processing system 150 can execute individual instructions or tasks. The components of the data processing system 150 can be connected or communicatively coupled to one another. The connection between the various components of the data processing system 150 can be wired or wireless, or any combination thereof. Counterpart systems or components can be hosted on other computing devices.

The data processing system 150 can communicate with one or more metering devices 118 via the network 140. In some cases, the data processing system 150 can include features or functionalities of the metering devices 118. In some other cases, the data processing system 150 can be a part of the metering device 118, such that the metering device 118 can perform certain features or functionalities of the data processing system 150.

The data processing system 150 can obtain measurements (e.g., raw or processed data or electric waveforms) from the one or more metering devices 118 within the utility grid 100. The data processing system 150 can receive or obtain the measurements from the metering devices 118 in response to each metering device 118 performing the measurement. The data processing system 150 may receive an aggregate of the measurements from the metering devices 118. In this case, each metering device 118 may store the measurements in a local memory and send the data in response to at least one of a predetermined time interval for a scheduled transmission, receiving a request for data from the data processing system 150, or a predetermined duration, size, or amount of data samples is collected. In some cases, the metering devices 118 can process the data prior to transmitting the data to the data processing system 150.

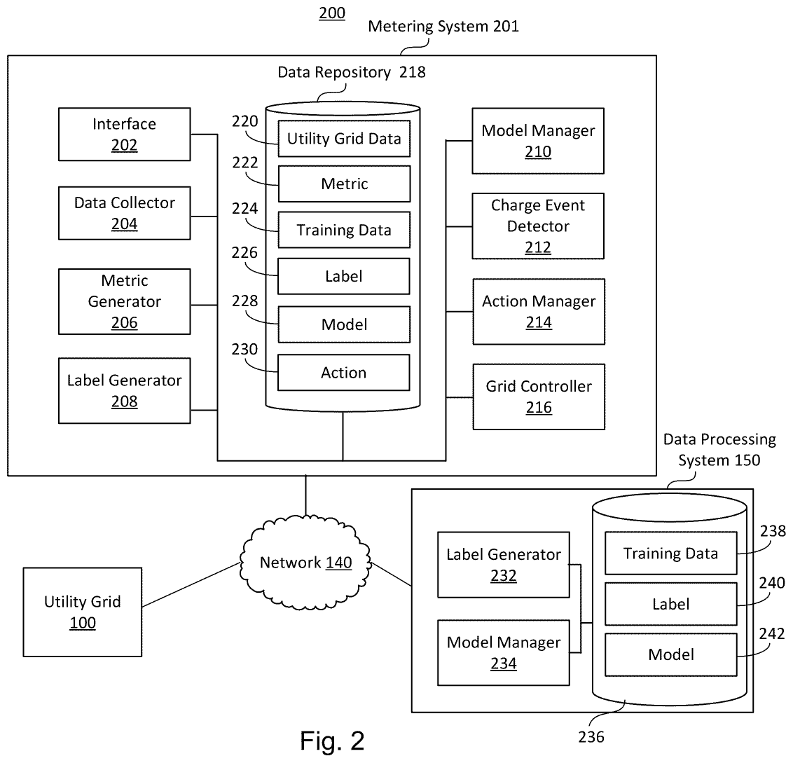

FIG. 2 depicts a block diagram illustrating an example system 200 for real-time detection of EV charging. The system 200 can include, interface with, access, or otherwise communicate with at least one utility grid 100, at least one data processing system 150, and at least one metering system 201. The metering system 201 can include one or more components (e.g., one or more processors, memory, databases, interfaces, etc.) configured to perform features or functionalities discussed herein for detection of EV charging (e.g., occurrences or events of EV charging) or managing the utility grid 100. The metering system 201 can include or correspond to one or more metering devices 118 located in the utility grid 100. In some cases, the metering system 201 can be a computing device local to or remote from the utility grid 100 or the data processing system 150. In some other cases, the metering system 201 can be a part of or perform one or more functionalities similar to the data processing system 150. The metering system 201 can transmit or receive data to or from other components (e.g., utility grid 100 or data processing system 150) of the system 200 via the network 140. The utility grid 100 and the network 140 can be referred to in conjunction with FIG. 1. The one or more devices, components, or systems (e.g., data processing system 150, metering system 201 (or metering devices 118), etc.) of the utility grid 100 or the system 200 can be composed of hardware, software, or a combination of hardware and software components.

The metering system 201 can include or correspond to at least one metering device 118, such as one of the metering devices 118 configured to perform one or more features (e.g., collect and process electricity characteristics) for EV charging detection. The metering system 201 can be located within the utility grid 100. For example, the metering system 201 can be positioned, installed, or provided at a location downstream from the substation 104 on the utility grid 100 that distributes electricity. Other metering systems can be distributed or installed throughout the utility grid 100, configured to perform one or more features or functionalities similar to the metering system 201. In various cases, the metering systems (including the metering system 201) can correspond to or include edge devices within the utility grid 100.

The metering system 201 can receive and process data locally on the utility grid 100. In some cases, the metering system 201 can forward or delegate one or more features or functionalities to another computing device local to or remote from the utility grid 100. For instance, the metering system 201 can transmit data to the data processing system 150 executing in a cloud computing environment or distributed computing environment. In this case, the metering system 201 may perform a portion of the functionalities for processing information (e.g., electrical characteristics) local to the utility grid 100 and the data processing system 150 may perform another portion of the functionalities for processing the information (or processed data from the metering system 201).

The metering system 201 can include one or more components for EV charging detection within the utility grid 100 (e.g., electricity distribution grid), for instance, at least one interface 202, at least one data collector 204, at least one metric generator 206, at least one label generator 208, at least one model manager 210, at least one charge event detector 212, at least one action manager 214, at least one grid controller 216, and at least one data repository 218. Each of the components (e.g., interface 202, data collector 204, metric generator 206, label generator 208 at least one model manager 210, charge event detector 212, action manager 214, grid controller 216, or data repository 218) of the metering system 201 can be implemented using hardware or a combination of software and hardware. Each component of the metering system 201 can include logical circuitry (e.g., a central processing unit or CPU) that responds to and processes instructions fetched from a memory unit (e.g., memory 715 or storage device 725). Each component of the metering system 201 can include or use a microprocessor or a multi-core processor. A multi-core processor can include two or more processing units on a single computing component. Each component of the metering system 201 can be based on any of these processors, or any other processor capable of operating as described herein. Each processor can utilize instruction level parallelism, thread level parallelism, different levels of cache, etc. For example, the metering system 201 can include at least one logic device such as a computing device or server having at least one processor to communicate via the network 140.

The components and elements (e.g., interface 202, data collector 204, metric generator 206, label generator 208 at least one model manager 210, charge event detector 212, action manager 214, grid controller 216, or data repository 218) of the metering system 201 can be separate components, a single component, or part of the metering system 201. For example, individual components or elements of the metering system 201 can operate concurrently to perform at least one feature or function discussed herein. In another example, components of the metering system 201 can execute individual instructions or tasks. In yet another example, the components of the metering system 201 can be a single component to perform one or more features or functions discussed herein. The components of the metering system 201 can be connected or communicatively coupled to one another, such as via the interface 202. The connection between the various components of the metering system 201 can be wired or wireless, or any combination thereof. Counterpart systems or components can be hosted on other computing devices.

The interface 202 can interface with the network 140, devices within the system 200 (e.g., data processing system 150 or utility grid 100), or components of the metering system 201. The interface 202 can include features and functionalities similar to the communication interface of one or more metering devices 118 to interface with the aforementioned components, such as in conjunction with FIG. 1. For example, the interface 202 can include standard telephone lines LAN or WAN links (e.g., 802.11, T1, T3, Gigabit Ethernet, Infiniband), broadband connections (e.g., ISDN, Frame Relay, ATM, Gigabit Ethernet, Ethernet-over-SONET, ADSL, VDSL, BPON, GPON, fiber optical including FiOS), wireless connections, or some combination of any or all of the above. Connections can be established using a variety of communication protocols (e.g., TCP/IP, Ethernet, ARCNET, SONET, SDH, Fiber Distributed Data Interface (FDDI), IEEE 802.11a/b/g/n/ac CDMA, GSM, WiMax and direct asynchronous connections). The interface 202 can include at least a built-in network adapter, network interface card, PCMCIA network card, EXPRESSCARD network card, card bus network adapter, wireless network adapter, USB network adapter, modem, or any other device suitable for interfacing one or more devices within the system 200 to any type of network capable of communication. The interface 202 can communicate with one or more aforementioned components to receive data from at least one of the utility grid 100 or the data processing system 150, such as data representative of electricity distribution to or consumed by individual metering devices 118 within the utility grid 100 or instructions from the data processing system 150.

The data collector 204 can obtain or collect electrical data within the utility grid 100. The electrical data can include data samples of an electrical waveform corresponding to electricity (e.g., electrical signals) distributed at or to the location of the metering system 201 on the utility grid 100. For example, the data collector 204 can collect electrical data in residential areas (e.g., residential homes), such as to measure the electricity consumed or drawn at the consumer site 119. The residential home may include at least one EV charger. In various cases, the data collector 204 can receive relatively high-resolution data, such as at least 1 kHz or 10 kHz of voltage data. In various cases, the electrical data discussed herein can be at least one of voltage data, current data, or power data, among other types of electrical information.

For example, the data collector 204 can obtain electrical waveform data (e.g., voltage waveform data or current waveform data) corresponding to electricity consumed by at least one load within the utility grid 100 and measured by at least one of the metering devices 118. The measured electricity (e.g., voltage measurement or current measurement) can represent or indicate the electrical consumption at the consumer site 119 (or residential home). In this example, the metering system 201 can correspond to or be in communication with the metering device 118 via the network 140. The interface 202 can receive at least one of voltage waveform data or current waveform data from the metering device 118 periodically or in response to the metering device 118 measuring the electricity. The data collector 204 can obtain the electrical waveform data from the metering device 118 via the interface 202 in communication with the network 140.

In another example, the metering system 201 can correspond to or include the metering device 118, including the features or functionalities of the metering device 118. The metering system 201 (or the metering device 118) can include one or more sensors (e.g., voltage sensors) communicatively coupled with the metering system 201 or one or more components of the metering system 201. The one or more sensors can detect or measure the electricity (e.g., voltage or current) distributed over the utility grid 100 to generate at least one of the voltage waveform data or the current waveform data. The one or more sensors can perform the measurement at a predefined sampling rate according to their configurations or capabilities. The metering system 201 can obtain the electrical measurement over one or more time intervals. The data collector 204 can obtain, detect, or measure the electricity at various time intervals.

For simplicity and for purposes of providing examples herein, the data collector 204 can detect voltage or current associated with the electricity consumed by at least one load within (or electricity distributed on or over) the utility grid 100 during at least one of the time intervals, such as a first time interval. In some cases, the data collector 204 can detect the voltage and current synchronously or simultaneously. The metering system 201 (or component(s) of the metering system 201) can use the detected voltage or current to determine whether at least a portion of the electricity consumed by the load within the utility grid 100 is used for EV charging. In some configurations, both voltage and current information may be utilized synchronously to perform the features or operations discussed herein. In some other configurations, the metering system 201 may use voltage information or current information independently or alternatively. The data collector 204 can store the collected data in the data repository 218.

The metric generator 206 can determine (or compute) one or more metrics associated with the electricity delivered over the utility grid in at least one of the time intervals. The metric generator 206 can determine the one or more metrics based on or according to the voltage and current detected by the metering device 118 or the sensor of the metering system 201. The metrics can include at least one of a voltage harmonic metric, a current harmonic metric, or a power metric, among other types of metrics.

The metric generator 206 can process the voltage and current information (e.g., raw electrical data) to determine the voltage harmonic metric and the current harmonic metric, respectively, for a time interval. For example, the metric generator 206 may utilize or perform Fourier analysis to determine the frequency content (e.g., harmonic components) of the electrical waveform, such as the fundamental frequency and harmonic frequencies. The fundamental frequency can refer to the frequency associated with the electricity consumed by at least one load within (or electricity distributed over) the utility grid 100 under relatively normal conditions, for instance, one of 50 Hz, 60 Hz, etc. Based on the fundamental frequency and the harmonic frequencies, the metric generator 206 can perform at least one suitable statistical technique to determine (or compute) a voltage harmonic and a current harmonic over a predefined time window, such as over 0.1 seconds. The predefined time window can be a portion of the time interval associated with the voltage harmonic metric.

The metric generator 206 can determine individual voltage harmonics or current harmonics over multiple time windows. The metric generator 206 can aggregate the voltage harmonics determined over the time windows to generate the voltage harmonic metric for the time interval (e.g., 1 second, 5 seconds, 10 seconds, or 15 seconds). The metric generator 206 can aggregate the current harmonics determined over the time windows to the current harmonic metric for the time interval. In such cases, for example, each voltage harmonic metric can include one or more voltage harmonics, and each current harmonic metric can include one or more current harmonics. In this case, the time interval may be the first time interval associated with the voltage harmonic metric or the current harmonic metric, for example.

Examples of the at least one statistical technique to determine the electrical harmonics can include, but is not limited to, largest harmonic, largest harmonic value, largest harmonic phase shift, second largest harmonic, second largest harmonic value, second largest harmonic phase shift, total harmonic distortion mean, total harmonic distortion mean, total harmonic distortion standard deviation, total harmonic distortion 90th quantile, total harmonic distortion 80th quantile, total harmonic distortion 10th quantile, etc.

The largest harmonic can correspond to an integer number (e.g., in multiple of the fundamental frequency, such as 60 Hz) of the harmonic with the largest magnitude. The largest harmonic value can correspond to the magnitude of the largest harmonic. The largest harmonic phase shift can correspond to the phase shift (e.g., lagging or leading) between the phase of the voltage waveform and the current waveform at the frequency of the largest harmonic. The second largest harmonic can correspond to an integer number (e.g., in multiple of the fundamental frequency) of the harmonic with the second largest magnitude. The second largest harmonic value can correspond to the magnitude of the second largest harmonic. The second largest harmonic phase shift can correspond to the phase shift (e.g., lagging or leading) between the phase of the voltage waveform and the current waveform at the frequency of the second largest harmonic.

The total harmonic distortion mean can correspond to the mean of the total harmonic distortion (THD) computed for a subset of windows within a time interval (e.g., a larger window) associated with the statistics being recorded or reported, such as applied or used for one or more statistical techniques herein. The THD can be calculated as or correspond to the first equation using odd harmonics. The total harmonic distortion mean can correspond to the median of the total harmonic distortion. The total harmonic distortion standard deviation can correspond to the standard deviation of the total harmonic distortion. The total harmonic distortion 90th quantile can correspond to the 90th quantile of the total harmonic distortion. The total harmonic distortion 80th quantile can correspond to the 80th quantile of the total harmonic distortion. The total harmonic distortion 10th quantile can correspond to the 10th quantile of the total harmonic distortion.

In another example, the metric generator 206 can determine the power metric over the time interval. The power metric can include a set of instantaneous power (e.g., including at least one of real power and reactive power) associated with the voltage and current detected by the metering system 201 or the metering device 118. For example, the metric generator 206 can determine (or compute) an instantaneous power based on the voltage and current data over a time window (e.g. 0.1 seconds). The metric generator 206 can determine the instantaneous power using an instantaneous power formula, such as instantaneous power (P)=Re{V*×I}. The metric generator 206 can determine multiple instantaneous powers over respective time windows.

The time windows associated with the instantaneous powers can be similar to the time windows associated with the voltage harmonics or the current harmonics. For instance, the metric generator 206 may determine the instantaneous powers synchronously with the voltage harmonics or current harmonics. The metric generator 206 can aggregate the instantaneous powers determined over the time windows to generate a power metric in the time interval (e.g., the first time interval). In this case, the time interval can correspond to an aggregation of the multiple time windows.

The one or more metrics can be used to identify or capture an electrical transient, or other characteristics of electricity consumed by at least one load within the utility grid 100 (or distributed over the utility grid 100, such as to the load). The electrical transient can refer to or indicate the changes in the electrical consumption within or electricity distributed over the utility grid 100, such as an increase (or ramp up) or decrease (or ramp down) of energy over a relatively short timeframe, such as over 0.1 seconds. In some cases, the metric generator 206 can determine at least one of the voltage harmonic metric, the current harmonic metric, and the power metric to downsample the electrical data captured by the sensor, while allowing the transient to be obtained. In some configurations, the electrical transient can be used, in part, as an indicator of whether an EV charging event has occurred, such as based on the correlation of captured electrical transient (e.g., the one or more metrics) with historical electrical transient indicative of an EV charging event.

The metric generator 206 can store the generated metrics in the data repository 218. In some cases, the metric generator 206 can provide the generated metrics to the data processing system 150 for storage or processing.

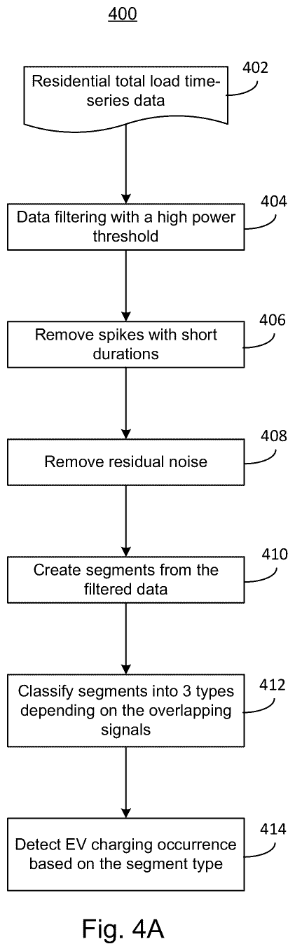

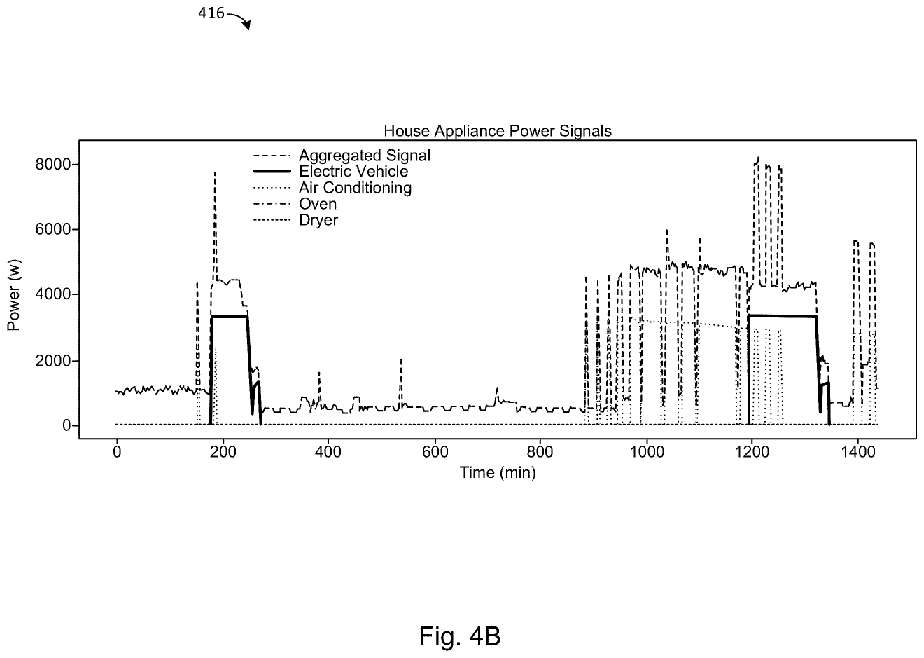

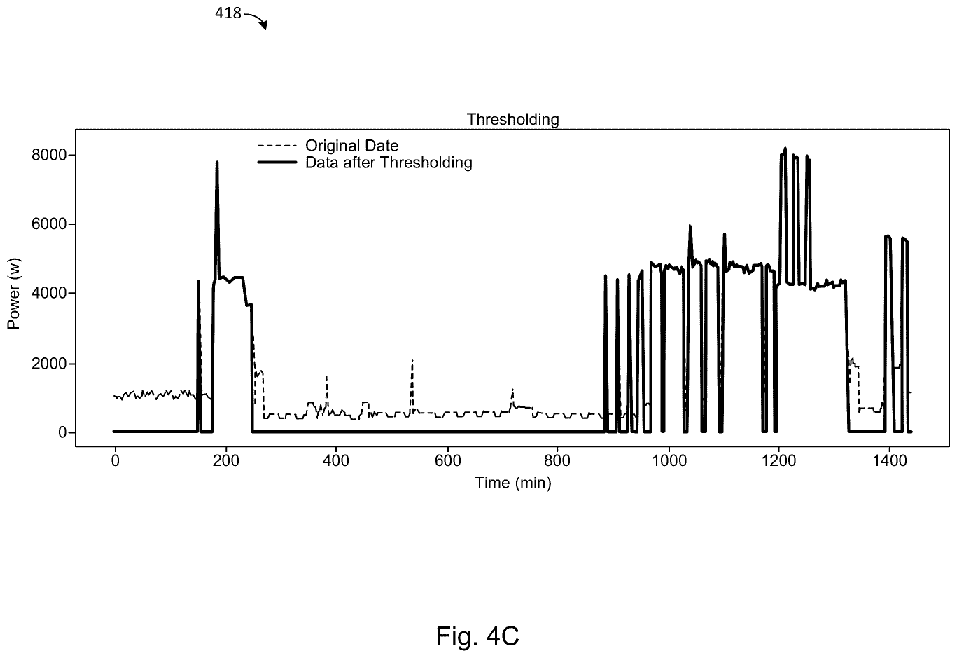

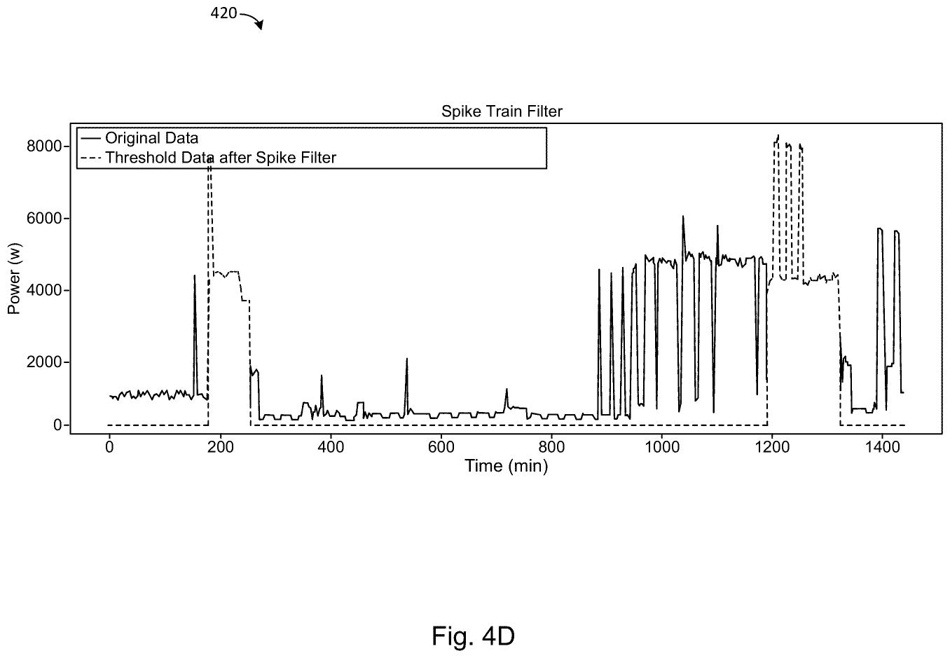

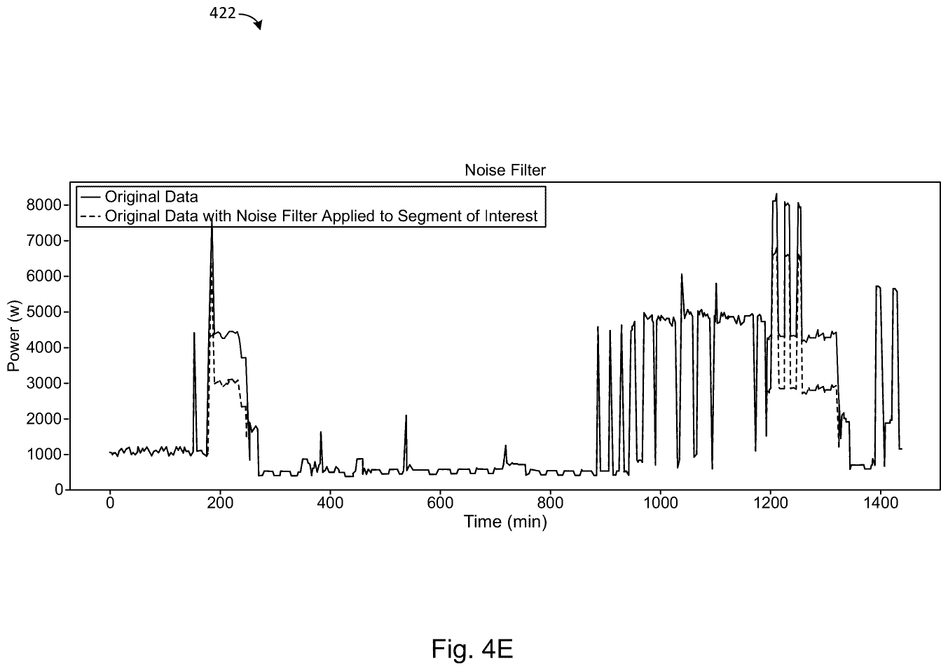

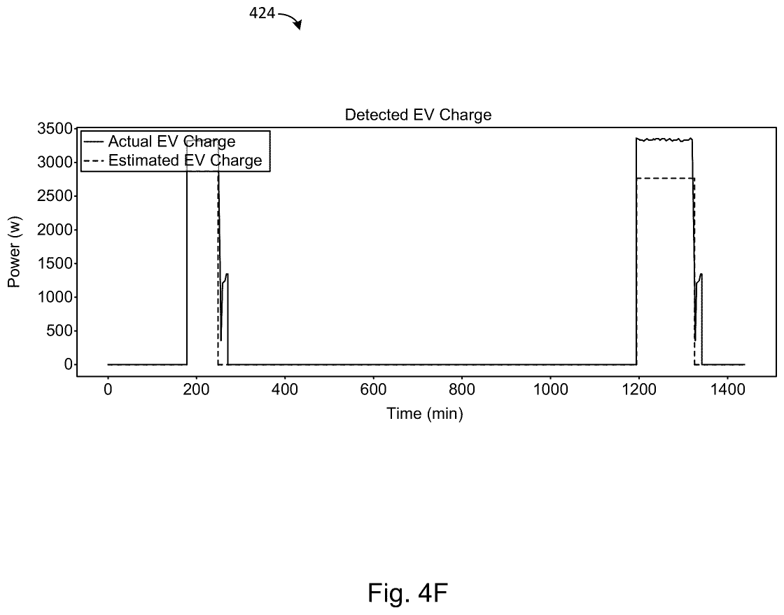

The label generator 208 can generate one or more labels or label data representing whether the time interval (or a segment of the time interval) is associated with an EV charging event. The labels generated by the label generator 208 can be used, at least in part, for training a model to perform real-time EV charging detection. In some cases, one or more operations or procedures of the label generator 208 to generate the label data can be described in conjunction with at least one of FIGS. 4A-F, for example.

Prior to generating the labels, the label generator 208 can identify or detect potential EV charging occurrences or events associated with historical electrical data distributed over the utility grid 100, e.g., to consumer site 119 or residential home. The historical electrical data can include or refer to historical residential load data measured with a predefined sampling rate (e.g., 1 Hz) or historical electrical signals. The label generator 208 can generate the one or more labels for various time intervals (e.g., time durations or timestamps) of the historical electrical data according to whether the EV charging events are identified. For instance, the label “0” can be assigned to time intervals when EV charging is not detected, and the label “1” can be assigned to time intervals when EV charging is detected. In some configurations, the label “1” can be assigned to time intervals when EV charging is not detected, and the label “0” can be assigned to time intervals when EV charging is detected.

For example, to determine the occurrences of EV charging, the label generator 208 can obtain historical electrical data (e.g., residential load time-series data), such as from the metering device 118 or from the data repository 218 storing the historical electrical data. In some cases, the metering system 201 may obtain the historical electrical data from the data processing system 150. In this case, the historical electrical data used for label generation can include or correspond to at least historical power data, such as instantaneous powers or power metrics. In some cases, the label generator 208 may obtain or use the voltage data or the current data to perform the label generation.

In some cases, the historical electrical data can include relatively lower resolution data, such as 1 Hz data, or the label generator 208 may downsample the historical electrical data for determining EV charging occurrences or generating the label. The label generator 208 can downsample the historical electrical data by computing a root-mean-square (RMS) value for each time window (e.g., every 1 second), among other aggregation techniques. The label generator 208 can use the downsampled historical electrical data for label generation herein, for example. Downsampling can refer to or include, for example, reducing the amount of data in a dataset by removing or aggregating some of the data points. Downsampling the dataset can improve the efficiency of processor computations or network transmissions.

After obtaining the historical electrical data (e.g., historical power), the label generator 208 can perform at least one data filtering technique to filter the historical power data having the power (e.g., magnitude of the power) at or above a predetermined threshold (e.g., power threshold). For example, the label generator 208 may filter (or extract) the historical power data to obtain filtered power data (e.g., sometimes referred to generally as filtered data), where the filtered power data can include historical power data at or above the predetermined threshold. The predetermined threshold can include, for example, 2.5 kW, 2.8 kW, 3 KW, or other configured thresholds. The filtered power data may be associated with a potential EV charging occurrence.

The label generator 208 can remove at least a portion of the filtered power data with a relatively short duration. The removal of the portion of the filtered power data with a relatively short duration can be referred to as spike filtering. For example, the label generator 208 can be configured with a duration threshold of 5 minutes, 10 minutes, 20 minutes, etc. If the duration of a portion of the filtered power data (associated with electrical power at or above the power threshold) is less than the duration threshold, the label generator 208 can remove the respective portion from the filtered power data.

After removing the power spike, the label generator 208 can filter or remove residual noise from the filtered data. To remove the residual noise, the label generator 208 can apply a noise filtering technique to one or more segments or portions of the filtered data, such as a high-pass filter, a low-pass filter, a band-pass filter, etc. The segments of the filtered data can correspond to the time when power is at or above the power threshold for at least the duration threshold. In some cases, the label generator 208 can apply the noise filtering technique to one or more segments of the historical power data (e.g., original data before filtering via the power threshold). In this case, the segments of the historical power data can include timestamps corresponding to the filtered data with power that are at or above the power threshold for at least the duration threshold.

The label generator 208 can generate or create one or more segments from the filtered data, such as segments (e.g., time segments) applied with the power threshold, duration threshold, or noise filter. The label generator 208 can classify the segments from the filtered data into one or more types (e.g., types of electrical consumption) according to overlapping electrical signals. The overlapping signals can refer to overlapping voltage or current signals from operating multiple electrical devices (e.g., residential appliances) simultaneously. The types of segments can include, for example, a first segment including at least one of EV charging, dryer, or oven, a second segment including EV charging, air conditioning (AC) system, or EV charging with a short-duration non-AC appliance, a third segment including EV charging overlapping with AC system, etc. The label generator 208 may perform the segmentation using at least one suitable segmentation technique, such as but not limited to using the non-intrusive load monitoring (NILM) technique.

The label generator 208 can detect or identify one or more EV charging occurrences based on the segment types. For example, the label generator 208 can determine that the remaining filtered data, with the magnitude of the power at or above the power threshold and the duration at or above the duration threshold, correspond to EV charging event(s). The label generator 208 can generate various labels (e.g., ‘1’ for EV charging or ‘0’ for non-EV charging) including a first label (e.g., ‘1’) for a first set of timestamps associated with EV charging occurrences and a second label (e.g., ‘0’) for a second set of timestamps associated with no EV charging. The label generator 208 can apply the labels associated with the timestamps to the historical electrical data, thereby segmenting EV charging occurrences from non-EV charging occurrences.

The label generator 208 can provide the labeled data to the model manager 210 for training a model for EV charging detection. In some cases, the label generator 208 may transmit the labeled data, such as the labeled historical electrical data to the data processing system 150 for training or executing the model.

In some configurations, the features or operations of the label generator 208 can be performed by the data processing system 150. For example, the metering system 201 (e.g., label generator 208), among other metering systems, can downsample the historical electrical data (e.g., with the relatively high-resolution data) for data transmission. The label generator 208 can downsample the historical electrical data by determining an RMS value for each time window (e.g., 1 second) of the historical electrical data. The metering system 201 can send the RMS values associated with the historical electrical data to the data processing system 150 for processing.

The model manager 210 can generate, train, or otherwise manage at least one model for EV charging detection. The model manager 210 can train the model using at least one suitable machine learning technique. The model can include or correspond to a convolutional neural network (CNN) model, long-short-term-memory (LSTM) model, support vector machine (SVM), or other types of models. In some cases, the model manager 210 can use the SVM to correct or adjust the timestamps associated with EV charging occurrence. In some other cases, the model manager 210 can use at least one or a hybrid of the CNN or LSTM model (e.g., CNN-LSTM model) for training or execution to detect EV charging occurrences. The model manager 210 may use other types of models for increasing training data accuracy (e.g., correcting EV charging timestamps) or detecting EV charging occurrences.

The model manager 210 can execute a model (e.g., SVM) to modify or update the timestamps associated with occurrences of EV charging and occurrences of no EV charging according to the labeled data and the generated metrics (or historically generated metrics). For example, the model manager 210 can obtain a first training data (e.g., labeled data sampled at a first resolution, such as 1 Hz) and a second training data (e.g., generated metrics sampled at a second resolution, such as 1 kHz or 10 kHz). The model manager 210 can obtain or retrieve the training data from the data repository 218 (or the data processing system 150). In this case, the second resolution can be greater than the first resolution. The labeled data can include or be referred to as historical load metrics for various timestamps, where each timestamp (e.g., each second) is assigned with one of the first label (e.g., indicating EV charging) or the second label (e.g., indicating no EV charging during the corresponding timestamp). The model manager 210 can provide the training data (or a first portion of the first training data and the second training data) as inputs to the model.

The model can be configured to correlate the second training data to the first training data, such as classifying the metrics (e.g., voltage harmonic metric, current harmonic metric, or power metric (sometimes referred to as harmonic and power dataset)) into the first label or the second label. For example, the model may interpolate the timestamps of the labeled data (or a portion of the labeled data associated with EV charging) to match or correspond to the timestamps of the metrics, including the voltage harmonic metric, current harmonic metric, or power metric. The model can identify the timestamps of the metrics and the labeled data indicative of the EV charging occurrence. According to the timestamps indicative of the EV charging occurrence, the model can correlate or classify the metrics corresponding to the timestamps into the first label. The model can determine the electrical transient or electrical characteristics of the metrics at or around these timestamps, which can indicate a start of the EV charging (e.g., EV charging ramp-up) or an end of the EV charging (e.g., EV charging ramp-down). The model can classify other timestamps associated with another portion of the metrics into the second label indicative of no EV charging.

Responsive to training the model to convergence (e.g., correlating the metrics to the respective label), the model manager 210 can provide another training data set (or a second portion of the first training data and the second training data) as inputs to the model. The model manager 210 can set thresholds for the ‘1’ and ‘0’ predictions, respectively. For example, the model manager 210 can set a first threshold (e.g., 1.1 or another upper limit) for output representing EV charging and a second threshold (e.g., −0.1 or another lower limit) for output representing no EV charging. The threshold may be predefined or predetermined by the administrator of the metering system 201 or the data processing system 150. The model manager 210 can execute the model, trained with the first and second training data (or the first portion of the training data), to determine the likelihood of EV charging occurrences. The model can output a value for each timestamp, where the value 1 can represent that the respective timestamp associated with the metrics and the labeled data is likely to be an EV charging occurrence, and the value 0 can represent that the respective timestamp is unlikely to be an EV charging occurrence. Values at or above the first threshold or at or below the second threshold can be considered as having higher accuracy (or fewer labeling errors) compared to values between the first and second thresholds. The output value can be obtained or received from the support vector machine trained using [0, 1]. The output value can include a floating point number (e.g., around the trained [0, 1] interval), such as −0.002, 0.345, 1.193, etc.

The model can compare the output values to the thresholds. The model can filter or extract the timestamps (of the metrics and the labeled data) associated with the output values that are at or above the first threshold or at or below the second threshold. Responsive to filtering these timestamps, the model manager 210 can generate EV charging time intervals for training the model (or another model, such as the CNN-LSTM model) to detect EV charging occurrence at the edge (e.g., at the metering device 118). The EV charging time intervals can be associated with the output values from the model that are at or above the first threshold. The model manager 210 can generate non-EV charging time intervals associated with the output values from the model that are at or below the second threshold.

For example, the model manager 210 can provide the training data as inputs to the model with the EV charging time intervals, such as filtered timestamps using the SVM. The model can identify the metrics associated with the EV charging time intervals and non-EV charging time intervals. According to the identified metrics, the model can determine electrical characteristics (e.g., electrical transient) indicative of EV charging occurrences, and electrical characteristics indicative of occurrences without EV charging. The model manager 210 can reiterate the process of filtering EV charging time intervals and training the model. The model manager 210 can provide additional training data to the model for updating or re-training the model.

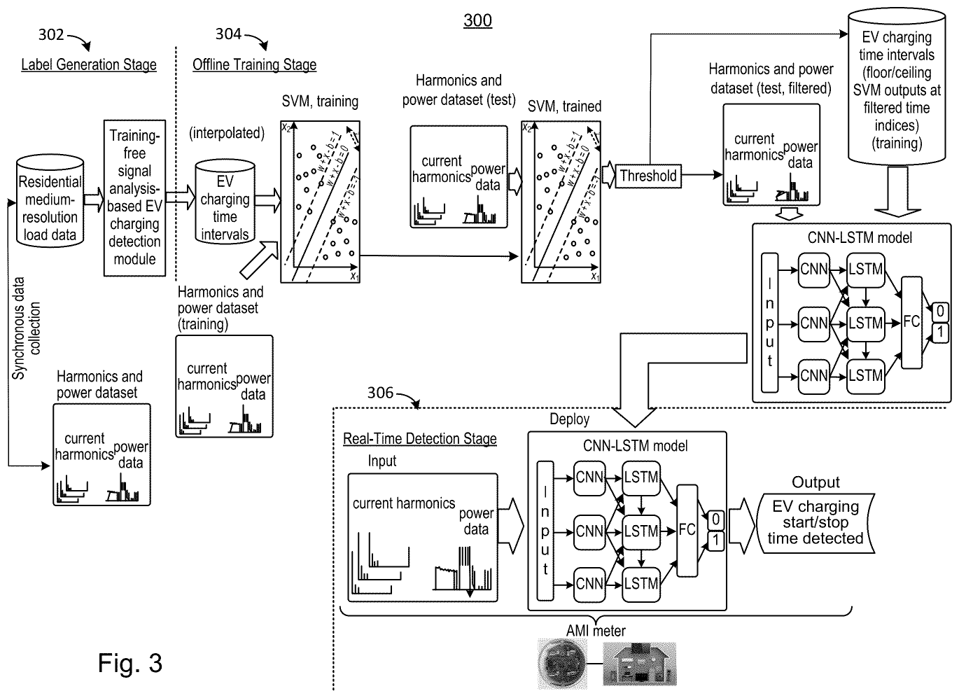

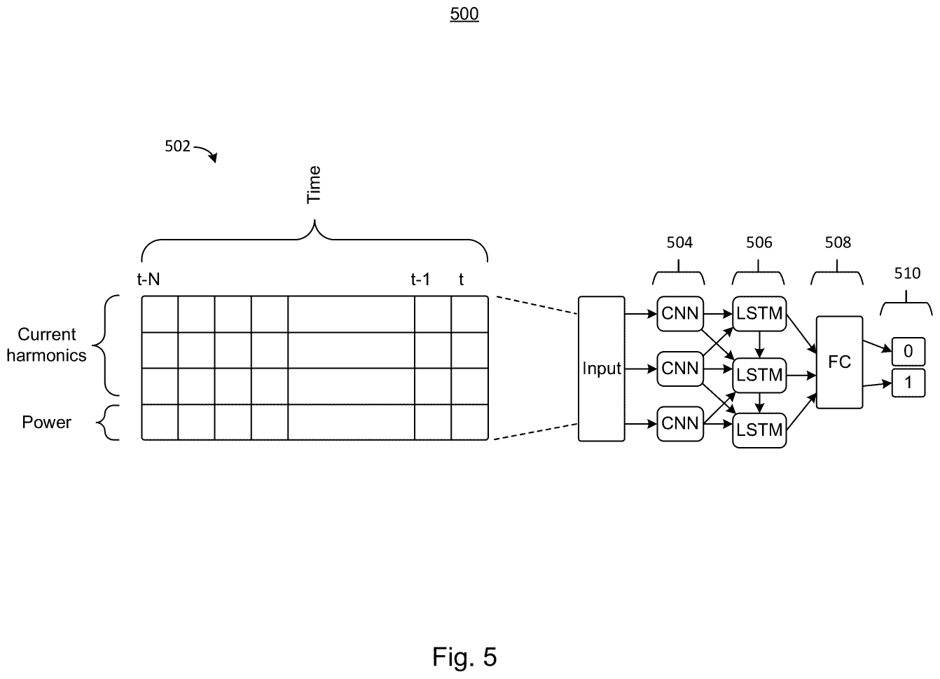

Subsequent to training the model with classified or labeled time intervals and metrics, the model manager 210 can deploy the model to detect EV charging occurrences. In some cases, the model manager 210 can store the model in the data repository 218. In some cases, the model manager 210 can provide the model to the data processing system 150 for execution. The model manager 210 may retrieve the model from the data repository 218 or the data processing system 150. The model manager 210 can update the model (e.g., input updated or additional data) periodically or responsive to receiving an indication from the administrator via the network 140 (e.g., from the data processing system 150 or a device within the utility grid 100). In some other cases, the model manager 210 can receive an updated or trained model from the data processing system 150. The processes, features, or operations for training, updating, or executing the model can be described in conjunction with at least one of FIG. 3 or 5, for example.

The charge event detector 212 can detect EV charging events or occurrences. The charge event detector 212 can input the metrics (e.g., the voltage harmonic metric, the current harmonic metric, or the power metric) into the model trained with machine learning and deployed on the metering system 201. The model can be used to determine the likelihood that at least a portion of the electricity delivered over the utility grid 100 in one or more time intervals is used to charge an EV, for example. The model can be configured to output a value indicative of the likelihood that the portion of the electricity is distributed for EV charging or not for EV charging. A value closer to ‘1’ can indicate a relatively higher likelihood that the electricity consumed by at least one load on the utility grid 100, such as a residential load, (or electricity distributed over the utility grid 100 (e.g., for the residential home or consumer site 119 associated with the metering system 201)) is for EV charging. A value closer to ‘0’ can indicate a relatively lower likelihood that the electricity consumed by the load within the utility grid 100 is for EV charging.

For example, the charge event detector 212 can receive the metrics from the metric generator 206 including at least one of the voltage harmonic metric, the current harmonic metric, or the power metric. The charge event detector 212 can provide these metrics as inputs to the trained model. The charge event detector 212 can continuously or periodically (e.g., every second) provide the input data to the model. Responsive to receiving the metrics, the model can identify the electrical characteristics or patterns according to or based on the generated metrics. The model can compare the identified electrical characteristics to the learned electrical characteristics (e.g., sometimes referred to as template electrical characteristic(s) or historical electrical characteristic(s)) representing EV charging events.

The model can output a value representing the likelihood of respective time intervals (e.g., every second, 5 seconds, or other predetermined time intervals) corresponding to an EV charging occurrence or a non-EV charging occurrence. For example, if the identified electrical characteristics closely resemble or are similar to the learned electrical characteristics, the model can output a value of around ‘1’. Otherwise, if the identified electrical characteristics are not similar to the learned electrical characteristics, the model can output a value of around ‘0’. If the output value from the model is around ‘1’, such as at or above a predetermined threshold (e.g., 0.9 or 1.1), the charge event detector 212 can determine that the electricity consumed by the load within the utility grid 100 is associated with an EV charging event.

The charge event detector 212 can provide an indication of the EV charging event to the action manager 214 (or the data processing system 150) to determine an action to perform on the utility grid 100. In some cases, the charge event detector 212 may provide an indication that the EV charging event has ended to the action manager 214 (or the data processing system 150) based on the output value from the model being around ‘0’ or at or below the threshold. In some cases, the charge event detector 212 may determine the EV charging event has ended when the output value is below the threshold for at least one time interval (e.g., after 1 second, 5 seconds, or other predetermined time intervals).

The action manager 214 can receive an indication of an occurrence or a start of at least one EV charging event from the charge event detector 212. The action manager 214 can receive an indication of an end of the EV charging event (e.g., no EV charging occurrence) from the charge event detector 212. Based on whether there is an EV charging event, the action manager 214 can determine or select at least one action to be performed on the utility grid 100, such as by the grid controller 216. For instance, the action manager 214 can select an action associated with the performance of the utility grid 100 responsive to the likelihood of EV charging occurrence satisfying the threshold (e.g., at or above the threshold).

For example, when an EV occurrence is detected, the action manager 214 can select a predetermined action to allocate, generate, or distribute energy to the consumer site 119 or residential location initiating the EV charging event. The action may include increasing electricity generation (or allocation) to the residential location during the EV charging time intervals. The action may include increasing electricity generation (or allocation) to the residential location for at least a predetermined time duration, such as 20 minutes, 30 minutes, 45 minutes, etc. The action may include decreasing the electricity generation (or allocation) after the duration has expired.

In some cases, the action may include notifying one or more devices of the utility grid 100 indicating the start or end of the EV charging occurrence(s). In some other cases, the action can include providing an indication of the time intervals associated with the EV charging occurrences, such as the time when the EV charging starts, when the EV charging ends, the duration of the EV charging, etc. The action may include providing electrical consumption data (e.g., residential load data) to the one or more devices of the utility grid 100.

In some aspects, the action manager 214 can initiate an action including to provide an indication (e.g., alert or notification) of the EV charging in the one or more time intervals to the data processing system 150. In this case, the data processing system 150 can provide an instruction to the one or more devices of the utility grid 100 (e.g., similar to the grid controller 216) to execute the action.

In certain cases, the action manager 214 may initiate an action to change or update the load mix or electrical generation parameters at the residential location responsive to detecting the EV charging event. For example, the action can include discharging the battery when an EV charging event is detected, thereby not increasing the net load. Additionally or alternatively, the action manager 214 may send a signal to the data processing system 150 (or the cloud) to update a monitoring system or a tracking system (e.g., a utility EV charging pilot) or leverage EV charging, such as for a virtual power plant (e.g., to control or operate electrical generation according to electrical consumptions throughout the utility grid 100 from various sources, for instance, to enhance grid stability, improve demand response, or load balancing, among others).

The grid controller 216 can perform the action selected or determined by the action manager 214. For example, according to the selected action, the grid controller 216 can send at least one signal to the one or more devices within the utility grid 100 for managing electrical generation or electrical allocation to the residential location associated with the metering system 201 (or metering device 118), among other residential locations. The grid controller 216 may send at least one signal including data associated with the EV charging events. The grid controller 216 can execute the action to increase the performance of the utility grid 100 responsive to the likelihood of an EV charging event satisfying the predetermined threshold.

In some cases, the grid controller 216 can receive a selected action from the data processing system 150. For example, the data processing system 150 can receive at least one indication of the EV charging event from the metering system 201 (or other metering systems). The data processing system 150 can determine the action to be performed by the grid controller 216 in communication with the one or more devices of the utility grid 100. The data processing system 150 can send the selected action to the grid controller 216. Responsive to receiving the action, the grid controller 216 can execute the action, such as by instructing at least one device within the utility grid 100 to adjust the generation or allocation of electricity to the residential locations that initiated the EV charging in at least one time interval.

The data repository 218 can include, store, or maintain information or data collected, measured, obtained, or otherwise received as discussed herein. The data repository 218 may be referred to as a data storage, database, memory device, etc. The data repository 218 can include at least a utility grid data storage 220, a metric storage 222, a training data storage 224, a label storage 226, a model storage 228, and an action storage 230. The data repository 218 can include other types of storage to store information for EV charging detection. In some cases, information stored in the data repository 218 can be uploaded to or synced with the data repository 236 of the data processing system 150, among other cloud storage devices, or downloaded to the data repository 218 for processing. In some other cases, the information stored in the data repository 218 may be local to the metering system 201. The data repository 218 can be accessed by one or more components (e.g., data collector 204, metric generator 206, label generator 208, model manager 210, charge event detector 212, action manager 214, or grid controller 216) of the metering system 201, or at least one external or remote device, such as other metering systems within the utility grid 100, the data processing system 150, etc.

The utility grid data storage 220 can include, store, or maintain information related to the utility grid 100 obtained, measured, or detected by the metering system 201 (e.g., interface 202 or data collector 204). For example, the utility grid data storage 220 can store electrical data received or measured by the data collector 204, such as the voltage waveform data or current waveform data measured by the metering system 201. The utility grid data storage 220 can store timestamps of when the data are logged or stored in the data repository 218. In some cases, the utility grid data storage 220 can include the identifier of the metering system 201, for instance, to be provided to the data processing system 150 during data transmission. In some other cases, the utility grid data storage 220 can include the geographical location of the metering system 201.

The metric storage 222 can include, store, or maintain the metrics generated by the metric generator 206. For example, the metric storage 222 can store the metrics generated by the metric generator 206 responsive to processing the electrical data, such as voltage or current. The metrics can include at least one of the voltage harmonic metric, current harmonic metric, or power metric, among others. The power metric may be one or more RMS values associated with respective time windows. The metric storage 222 may store timestamps associated with the generated metrics.

The training data storage 224 can include, store, or maintain training data for training the model. The training data storage 224 can be accessed by the label generator 208 or the model manager 210 to train, update, or otherwise manage the at least one model. In some cases, the data stored in the training data storage 224 can be obtained or downloaded from the data processing system 150, such that the model can be trained on the metering system 201. In some other cases, the data stored in the training data storage 224 can be sent or uploaded to the data processing system 150, such that the data processing system 150 can update the model. The training data stored in the training data storage 224 can be updated periodically or responsive to receiving new training data from the data processing system 150. The training data storage 224 can be accessed (e.g., by the label generator 208 or model manager 210) periodically for updating the model or responsive to receiving an indication to update the model. The training data can include historical electrical data, historical metrics, timestamps, or other information for training the model.

The label storage 226 can include, store, or maintain labels generated by the label generator 208. The label storage 226 can be accessed by the model manager 210 for training the model using the labels generated by the label generator 208. For example, the label storage 226 can store the timestamps associated with the electrical data, metrics, or training data. The label storage 226 can store the labels associated with the timestamps. The label ‘1’ can indicate an occurrence of EV charging associated with the timestamp. The label ‘0’ can indicate no occurrence of EV charging at the timestamp. In some cases, the label storage 226 may upload the label data to the label storage 240 of the data processing system 150.

The model storage 228 can include, store, or maintain at least one model for EV charging detection. The model storage 228 can receive or obtain the model generated or managed by the model manager 210. In some cases, the model storage 228 can receive the model from the data processing system 150. The model storage 228 can be accessed by the model manager 210 for updating or executing the model. The model stored in the model storage 228 can be trained or updated periodically or responsive to additional training data (e.g., stored or to be stored in the training data storage 224). In some cases, the model storage 228 may replace an existing model with an updated model received from the data processing system 150. In some other cases, the model storage 228 may receive a new model from the model manager 210. One or more models stored in the model storage 228 can be updated or discarded according to the instructions from the administrator, for example. In some cases, the model storage 228 can be synched with the model storage 242 of the data processing system 150.

The action storage 230 can include, store, or maintain various actions selectable by the action manager 214 or executable by the grid controller 216. The actions can include or correspond to executable codes, instructions, or commands for execution by the grid controller 216. The actions can be predetermined by the operator or the administrator of the utility grid 100. For example, the metering system 201 (and one or more other metering systems) may receive the predefined actions from the data processing system 150 to store locally in the action storage 230. The action storage 230 can store new or updated actions upon receiving the actions from the data processing system 150. The action storage 230 can remove at least one predefined action responsive to a command from the data processing system 150. In some cases, the action storage 230 can store similar types of actions as those stored in other metering systems or the data processing system 150 (e.g., the actions synched to other systems or devices). The action may include, for example, sending an alert to the data processing system 150 of the EV charging event, instructing the one or more devices in the utility grid 100, or sending information associated with the EV charging event to the data processing system 150, among other actions performed by the metering system 201 or the data processing system 150 discussed herein.

In some cases, the metering system 201 can be different from the data processing system 150, for instance, the metering system 201 can correspond to or be associated with at least one of the metering devices 118. In this case, the data processing system 150 can be remote from the utility grid 100 and the metering systems. The data processing system 150 can receive data from the one or more metering systems, such as the metering system 201. The data received from the metering system 201 may include, for instance, at least a portion of the voltage data, current data, or power data, the one or more metrics generated by the metering system 201 based on the voltage and the current, or other data associated with the EV charging occurrence(s). In some cases, the data processing system 150 can receive an identifier from the metering system 201 indicating which of the metering systems within the utility grid 100 is providing the data. The data processing system 150 may receive downsampled data from the metering system 201, such as RMS values from respective time windows of the measured voltage and current data. By downsampling the data for upload to the data processing system 150, the communication bandwidth or network resources used for data transmissions can be reduced or maintained within a desired bandwidth threshold.

The data processing system 150 can include one or more components for at least model training, EV charging detection, among other functionalities discussed herein. The one or more components of the data processing system 150 can include, for instance, at least one label generator 232, at least one model manager 234, at least one data repository 236, or other components, such as one or more components as the metering system 201. The data repository 236 may be referred to as a memory device of the data processing system 150 or a remote database relative to the metering system 201. Each of the components (e.g., label generator 232, model manager 234, or data repository 236) of the data processing system 150 can be implemented using hardware or a combination of software and hardware. The data processing system 150 can include one or more components configured to one or more features or functionalities similar to the metering system 201.

The label generator 232 can be configured to perform features or functionalities similar to the label generator 208. For example, the label generator 232 can obtain historical electrical data (e.g., historical power data) from one or more metering systems. The label generator 232 can process the historical power data to determine time instances or intervals associated with at least one potential EV charging occurrence, such as according to at least one of the magnitude or duration of the historical power data. Based on the potential EV charging occurrence (or occurrences of no EV charging), the label generator 232 can generate the first label (e.g., ‘1’) or the second label (e.g., ‘0’) for the individual time intervals. By labeling the historical power data, the label generator 232 can generate labeled data for training the model.

For example, the label generator 232 can receive time-series data sampled at or downsampled to the first resolution (e.g., 1 Hz) corresponding to residential electric load (e.g., historical power data). The label generator 232 can detect, based on a threshold, one or more time intervals of EV charging in the time-series data. The threshold can include at least one of the magnitude of the residential electric load or the duration of the residential electrical load. The label generator 232 may detect the EV charging time intervals based on at least one of the magnitude of the residential electric load being at or above a power threshold or the duration of the residential electric load (at or above the power threshold) extending at least beyond a duration threshold. The threshold(s) may be predefined by the data processing system 150 or the administrator of the data processing system 150. According to the detected EV charging time intervals, the label generator 232 can label the time-series data to indicate the one or more time intervals of electric vehicle charging to generate labeled time-series data (e.g., sometimes referred to generally as labeled data).

The model manager 234 can be configured to perform features or functionalities similar to the model manager 210. For example, the model manager 234 can obtain the labeled data from the label generator 232 or from the data repository 236. The model manager 234 can use the labeled data and the one or more metrics from the one or more metering system 201 to train the model (or multiple models). The model manager 234 can periodically obtain data from the one or more metering systems. In some cases, the model manager 234 can obtain the data from the one or more metering systems responsive to an indication from the administrator to request data upload from the one or more metering systems. The model manager 234 may train, re-train, or update the model periodically (e.g., daily, weekly, or monthly) or responsive to an indication from the administrator. The model manager 234 can store the model in the data repository 236. In some cases, the model manager 234 can send the model to the one or more metering systems for real-time EV charging detection.

For example, the model manager 234 can receive a harmonics and power data set (e.g., the metrics) sampled at a second resolution greater than the first resolution for label generation, such as at 10 kHz (or 1 kHz) greater than the 1 Hz. The model manager 234 can input the labeled time-series data and the harmonics and power data set into the SVM (or other models) to train the SVM to classify the harmonics and power data set to indicate EV charging or no electric vehicle charging. The model manager 234 can use the trained SVM to filter a second harmonics and power data set (e.g., a subset of the metrics that satisfy likelihood thresholds) to generate a filtered second harmonics and power data set (e.g., filtered data). For instance, the SVM can output a value representing the likelihood of whether the associated subset of the metrics corresponds to an EV charging occurrence or no EV charging occurrence. The likelihood thresholds can include at least one of an upper limit and a lower limit. If the output value is at or above the upper limit, the model can determine that the subset of metrics is likely to be associated with an EV charging occurrence. If the output value is at or below the lower limit, the model can determine that the subset of metrics is likely to be associated with no EV charging occurrence. The model manager 234 can train the model, such as using a hybrid CNN-LSTM technique (or other types of machine learning techniques), with the filtered second harmonics and power data set.

The data repository 236 can include, store, or maintain information related to EV charging detection. In some cases, the data repository 236 may. The data repository 236 can include at least training data storage 238, label storage 240, and model storage 242. The data repository 236 can include other types of storage for storing information related to EV charging detection, such as information similar to the data repository 218. For example, the training data storage 238 may include or store training data similar to the training data from the training data storage 224 of the metering system 201 or other metering systems. The label storage 240 can include labels generated by the label generator 232. The label storage 240 may include labels generated by the one or more metering systems, such as similar to the label storage 226. The model storage 242 can include or store at least one model for EV charging detection. The model storage 242 may be accessed by the one or more metering systems for synchronizing the model or downloading the model for execution. In some cases, the model storage 242 can include or store the model similar to the model storage 228 or other models from other metering systems, for example.

FIG. 3 depicts a flow diagram 300 of an example overview for model generation and deployment. The flow diagram 300 can include a label generation stage 302, offline training stage 304, and real-time detection stage 306 for model generation and deployment. In this case, the term “offline” can be in the context of asynchronous to the real-time detection stage 306 (e.g., performing the detection and offline training simultaneously). The flow diagram 300 can include an initial data collection stage (not shown). The operations or procedures of the flow diagram 300 can be executed, performed, or otherwise carried out by the one or more components of the utility grid 100 (e.g., computing device, metering device 118, data processing system 150, or other devices), the system 200 (e.g., data processing system 150 or metering system 201), or computing device 700, etc. Certain operations discussed herein can be performed by either one of the metering device 118, the metering system 201, or the data processing system 150.

As an overview of the flow diagram 300, the initial data collection stage can include an edge device (e.g., metering device 118 or the metering system 201) collecting relatively high resolution (e.g., at least 10 kHz sampling rate) current data (or voltage data) at or near a location associated with an occurrence of EV charging. For example, the metering device 118 can be positioned at or near at least one residential home including at least one EV charger to measure the electricity consumed or drawn at the consumer site 119, such as residential loads or EV charger(s). The metering device 118 can downsample the collected dataset to produce a relatively lower resolution (e.g., from high-resolution to medium-resolution, such as from 10 k Hz to 1 Hz, among other conversions) load (e.g., instantaneous power) data over the time period of collecting the data. In various cases, the medium-resolution data can refer to data sampled at or downsampled to a resolution relatively lower than the high-resolution data, such as 100 Hz, 10 Hz, 1 Hz, etc. In some cases, the metering system 201 may collect the medium-resolution load data of the residential home synchronously or concurrent with collecting the high-resolution current data (e.g., used to generate the metrics).

At the label generation stage 302, the metering system 201 or the data processing system 150 (e.g., label generator 208 or label generator 232) can be configured to label or flag segments of the data (e.g., medium-resolution data) indicative of at least one occurrence of the EV charging (e.g., a time instance or duration when the EV charger is being utilized). The operations or procedures associated with the label generation stage 302 can be described in conjunction with at least one of FIGS. 4A-F. For example, FIG. 4A depicts a flow diagram of an example method 400 for offline charging detection associated with label generation stage 302, including ACTS 402-414.

At ACT 402, the metering system 201 can perform the data collection at or around the consumer site 119 to obtain residential load data (e.g., residential total load time-series data). An example depiction of the residential load data can be shown in at least FIG. 4B, such as in example graph 416. The load data of the example graph 416 can include aggregated signals, such as signals from the EV charger, air conditioning device, oven, and dryer, among other appliances or devices at the residential location. The load data may be sampled at or downsampled to a medium resolution (e.g., 1 Hz), for example.

In some cases, the metering system 201 (or the data processing system 150) can obtain the data from the metering devices 118. The metering system 201 can perform the features or operations in the label generation stage 302 offline (e.g., locally on the metering system 201). The metering system 201 can use the medium-resolution load data to determine the occurrences of EV charging. The metering system 201 can provide labels or classify the time segments or time intervals of the medium-resolution load data as charging (e.g., ‘1’) or not charging (e.g., ‘0’).

To generate or apply the label, the metering system 201 can perform one or more filtering techniques to satisfy the criteria for EV charging events. For example, at ACT 404, the metering system 201 can remove or filter out load data (e.g., sampled at the medium resolution) with a magnitude of less than the power threshold (e.g., 3 kW). The metering system 201 can maintain or extract load data with the magnitude of at least the power threshold. Using the total load data from graph 416 as an example, the metering system 201 can filter out load data with the magnitude of less than the power threshold to obtain the example graph 418 of FIG. 4C. As shown in FIG. 4C, the data segments with power consumption (e.g., electrical power distributed over the utility grid 100) at or above the power threshold (e.g., potentially associated with the EV charging events) can be separated from other segments with power consumption below the power threshold. In FIG. 4C, the power threshold can be around 3 KW, which can be configurable by the administrator of the data processing system 150 or the service provider of the metering device 118 or the metering system 201, for example.

After filtering the relatively low magnitude, at ACT 406, the metering system 201 can filter the load data with a duration of less than the duration threshold (e.g., less than 10 minutes, 20 minutes, or 30 minutes). Filtering the load data with a relatively short duration of less than the duration threshold can refer to removing spikes in the load data. As shown in example graph 420 of FIG. 3D, for example, the metering system 201 can remove spikes or electrical signals (or load data) with a relatively short duration from graph 418. The graph 420 can include the load data that are at or above the power threshold with the duration of at least the duration threshold.

At ACT 408, the metering system 201 can filter or remove residual noise from the data using at least one suitable noise filtering technique. For example, the metering system 201 can filter the frequency at or above an upper-frequency threshold, frequency at or below a lower-frequency threshold, etc., to remove residual noise. As shown in FIG. 4E, for example, an example graph 422 can depict the original data (e.g., original residential load data) and the original data applied with noise filter at one or more segments. The metering system 201 can apply the noise filter to at least one desired segment of the original data, such as segments associated with the load data having the magnitude at or above the power threshold and duration at or above the duration threshold.

At ACT 410, the metering system 201 can create or generate segments from the filtered data, such as responsive to filtering the relatively low magnitude, relatively short duration, etc. At ACT 412, the metering system 201 can classify the segments into various types depending on the overlapping signals. The types of segments can include at least one of 1) EV and/or dryer or oven, 2) EV or air conditioner (A/C) or EV with relatively short duration non-AC, or 3) EV overlapping with AC, among other classifications. The generation and classification of the segments can be performed using at least one suitable segmentation or labeling technique, such as but not limited to the NILM for monitoring EV charging.

At ACT 414, the metering system 201 can detect or estimate EV charging occurrences according to the classified segment type. For example, as shown in example graph 424 of FIG. 4F, the metering system 201 can extract the potential EV charging occurrences from the residential load data by performing the filtering. Responsive to performing the filtering, the metering system 201 can obtain the filtered data. The metering system 201 can classify or label the segments of the filtered data as ‘1’ for charging or ‘0’ for not charging. The example graph 424 can depict a time series of estimated EV charging occurrences (or filtered data) compared to the actual EV charging occurrences.

In some aspects, the metering system 201 may receive medium-resolution data or high-resolution data from the data processing system 150, such as simulated data generated using at least one suitable computation technique or simulation technique for model training purposes. In such cases, the metering system 201 (e.g., label generator 208) can receive an indication of time intervals associated with EV charging and no EV charging. The metering system 201 can label the time intervals based on the indication of EV charging occurrences and no EV charging occurrences.

The metering system 201 (e.g., metric generator 206) can process the high-resolution current data (e.g., measured synchronously with the medium-resolution load data) to determine or generate the harmonics and power dataset. The power can include or correspond to instantaneous power. The harmonics and power dataset can correspond to or be referred to as the metrics, including at least one of voltage harmonic metric, current harmonic metric, or power metric. The harmonics and power dataset can be computed over a predefined time window, such as 0.1 seconds. The metering system 201 can aggregate the metrics over a time interval (e.g., 5 seconds) to capture the electrical transient of EV charging ramp-up at the start of the charging event and EV charging ramp-down at the end of the charging event. As discussed herein, the metering system 201 can provide the metrics as input to the machine learning model.

At the offline training stage 304, the metering system 201 or the data processing system 150 (e.g., model manager 210 or model manager 234) can train at least one machine learning model. Using the time segment labels (e.g., labeled data) from the label generation stage 302 as ground truth (e.g., known “true”, “real”, or accurate information), the metering system 201 can use the high-resolution data, for instance, obtained from the metering devices 118 or the sensors of the metering system 201 (e.g., stored in the data repository 218) to train the model to identify or predict the occurrences of the EV charging events. The metering system 201 or the data processing system 150 can utilize any suitable machine learning technique to train the model, such as supervised learning, unsupervised learning, semi-supervised learning, or reinforcement learning, among other types of techniques. The model may include or correspond to the SVM model, CNN-LSTM model, etc.

Prior to training the model used for determining or predicting the EV charging occurrences, the metering system 201 (or the data processing system 150) can filter or remove potential labeling inaccuracies or errors. For example, the metering system 201 can interpolate the EV charging time intervals from the labeled data to match the resolution of the harmonics and power dataset (e.g., metrics generated from the high-resolution current data). As discussed herein, the harmonics and power dataset are obtained from similar time intervals as the residential load data used to obtain the labeled data. The metering system 201 can split the EV charging time intervals from the labeled data and the harmonics and power dataset into multiple subsets, such as a training subset and a test subset from different sections or portions of the labeled data and the harmonics and power dataset. The training subset and the test subset can include respective portions of the EV charging time intervals and the harmonics and power dataset. The training subset and the test subset can be used by the model for removing potential labeling errors.

The metering system 201 can use the training subset for training the model to convergence. For example, the metering system 201 can input the training subset into the model (e.g., SVM) for training or learning to classify the harmonics and power dataset into ‘1’ for EV charging and ‘0’ for no EV charging based on the labeled data. For example, the metering system 201 can execute the model to identify at least a portion of the harmonics and power dataset that corresponds to the EV charging time intervals. The metering system 201 can classify these time intervals as ‘1’. The metering system 201 can classify other time intervals as ‘0’ indicative of no EV charging. The metering system 201 can repeat the classification process for other EV time intervals and harmonics and power datasets.

Responsive to training the model, the metering system 201 can provide the test subset as input to the trained model (e.g., trained SVM). The metering system 201 can use the test subset for testing the output of the model, such as to update or continue training the model based on the accuracy of the model. For example, the metering system 201 can execute the trained model to classify the harmonics and power dataset of the training data into ‘1’ and ‘0’. Based on the learned characteristics of electricity from the training subset (or other training data), the model can compare the characteristics of the test subset to the learned characteristics. The model can output values closer to ‘1’ based on the characteristics of the test subset being relatively similar to the learned characteristics. The model can output values closer to ‘0’ based on the characteristics of the test subset being different from the learned characteristics (or relatively similar to the characteristics of no EV charging occurrences).

The metering system 201 can set thresholds for the EV charging predictions or determination. For example, the metering system 201 can set the first threshold (e.g., 1.1) associated with the ‘1’ prediction and the second threshold (e.g., −0.1) associated with the ‘0’ prediction. The thresholds can be predetermined by the data processing system 150. The metering system 201 can filter at least a first set of time intervals of the test subset corresponding to the model output values (e.g., floating point number) at or above the first threshold. The metering system 201 can use the first set of time intervals as the EV charging time intervals for training the model. The metering system 201 can filter at least a second set of time intervals of the test subset corresponding to the model output values at or below the second threshold. The metering system 201 can use the second set of time intervals as the no EV charging time intervals for training the model. The data associated with the first and second set of time intervals can correspond to or be referred to as filtered data (e.g., filtered test subset) corrected of potential labeling errors.

The metering system 201 can use the filtered data to train the model for EV charging detection or prediction. This model may be the same or different model from the model using the training subset and the test subset. For purposes of providing examples herein, the model for EV charging detection can include the CNN-LSTM model (e.g., hybrid model), although other types of machine learning model can be used.

The metering system 201 can train the model using the filtered data by computing or identifying the physics-informed features, such as voltage harmonics, current harmonics, or power, among other types of metrics, from the current data. The model (e.g., CNN layer) can be configured to perform feature or characteristic extraction. The CNN layer may be used to extract one or more features across the time and input variables, as the input dataset (e.g., time in the x-axis and the input variables in the y-axis), which may be thought of as or represented by image data. The model (e.g., LSTM layer) can be configured to capture or learn temporal patterns of the input data over various time steps. The one or more features from the CNN layer can be fed into the LSTM layer (or model) for learning the temporal and inter-variable patterns in the data, for instance, to capture the time- or variable-dependent relationships signaling the start and stop times of the EV charging event. For example, the metering system 201 can input the filtered data to train the model to identify patterns or characteristics of the metrics (e.g., harmonics and power) that represent EV charging events based on the time intervals indicative of EV charging occurrences. The metering system 201 can train the model to identify patterns or characteristics of the metrics (e.g., harmonics and power) that represent other power consumption at the consumer site 119 when there is no EV charging. Responsive to processing the data, the model (e.g., fully-connected (FC) layer) can output a value of ‘0’ or ‘1’ (or around ‘0’ or ‘1’) for individual time intervals based on whether the patterns of the metrics likely represent an occurrence of EV charging or no EV charging. In some cases, around half of the training data for the model can include EV charging data and around another half of the training data for the model can include non-EV charging data. The model can associate the ‘0’ and ‘1’ from the filtered data to the metrics for detecting the presence of EV charging or the presence of no EV charging, for example.

After training the model, the metering system 201 can deploy the model for real-time EV charging detection. The metering system 201 can deploy the model at the edge of the utility grid 100, such as at the metering device 118 located at or around a respective residential home. In some cases, the metering system 201 can test the model using testing data. The testing data can include a set of metrics and known EV charging time intervals. In this case, the metering system 201 can execute the model to determine whether one or more time intervals of the testing data are associated with EV charging or no EV charging. The metering system 201 can compare the output from the model (e.g., ‘1’ or ‘0’ associated with individual time intervals) to the known EV charging time intervals. If the accuracy of the output from the model compared to the actual EV charging occurrences are at or above an accuracy threshold, such as 95%, 98%, or 99% accuracy, the metering system 201 can deploy the model for the real-time detection stage 306. Otherwise, the metering system 201 may provide additional or new training data for the model, for instance, to re-train or update the model using the additional training data.

At the real-time detection stage 306, the metering system 201 (or the edge devices, such as the metering devices 118) can be configured to detect EV charging in real-time using the trained model. Detecting EV charging in real-time can refer to performing the detection responsive to obtaining additional electrical data (e.g., current data) or at least one predetermined time interval (e.g., 1 second or 5 seconds) of the electrical data.

In some cases, the metering system 201 can be configured to train and deploy the model (e.g., local training). In some other cases, the trained model can be deployed by the data processing system 150 (e.g., remote training). For example, the metering system 201 can receive the trained model from the data processing system 150. In some configurations, the metering system 201 may receive additional training data for updating the model. In some other configurations, the metering system 201 can receive a new model from the data processing system 150, such as to replace with the existing or current model. The execution of the model can be described in conjunction with at least FIG. 5, for example.

FIG. 5 depicts an illustration 500 of an example harmonics and power dataset used as input 502 to the model. For purposes of providing examples herein, the model can be a hybrid machine learning model trained using CNN and LSTM techniques (e.g., CNN-LSTM hybrid architecture), although other types of machine learning techniques or machine learning models can be used. As shown, in the case of CNN-LSTM model, the model can include at least one CNN layer 504, at least one LSTM layer 506, and at least one FC layer 508.

As shown in FIG. 5, the input 502 for the model can include physics-informed features computed from at least current data. Additionally or alternatively, the physics-informed features can be computed from voltage data. For example, the physics-informed features can include or correspond to metrics, such as at least one of voltage harmonics, current harmonics, or power. Responsive to obtaining the current data, the metering system 201 can generate the metrics for input 502 to the model. The model can receive the input 502 from the metering system 201. At the CNN layer 504, the model can extract the features from the input 502, such as the magnitude of the power metric at a time interval, the duration of the magnitude of the power metric in the time interval, the voltage harmonics in the time interval, or the current harmonics in the time interval. At the LSTM layer 506, the model can determine the temporal patterns or characteristics of the metrics in the time interval based on the extracted features, for example. After processing the input 502 via the CNN layer 504 and the LSTM layer 506, at the FC layer 508, the model can generate an output 510 associated with the time interval, among other time intervals. The output 510 can include a value of either ‘1’ for EV charging or ‘0’ for no EV charging based on the generated metrics (e.g., harmonics and power dataset). In some cases, the output 510 may include a value of around ‘1’ or around ‘0’ based on the probability or likelihood of the time interval including the EV charging or no EV charging.

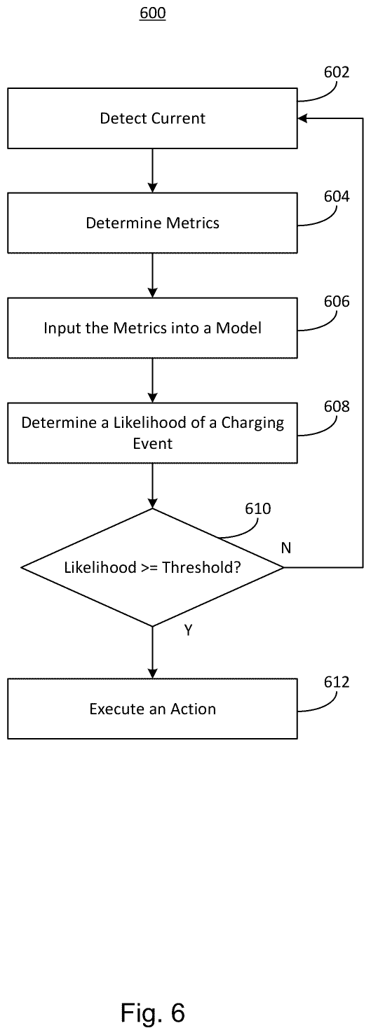

FIG. 6 depicts a flow diagram of an example method 600 for real-time detection of EV charging. The example method 600 can be executed, performed, or otherwise carried out by the one or more components of the utility grid 100 (e.g., computing device, metering device 118, data processing system 150, or other devices), the system 200 (e.g., data processing system 150 or metering system 201), or computing device 700, etc. Although the steps of the method 600 are shown to be performed by one of the metering system 201 or the data processing system 150, certain steps discussed herein can be performed by either one of the metering system 201 or the data processing system 150. The method 600 can include detecting current (or voltage), at ACT 602. At ACT 604, the method 600 can include determining metrics. At ACT 606, the method 600 can include inputting the metrics into a model. At ACT 608, the method 600 can include determining a likelihood of a charging event. At ACT 610, the method 600 can include determining whether the likelihood satisfies a threshold. At ACT 612, the method 600 can include executing an action.

In further detail, at ACT 602, the metering system can detect, via at least one sensor of the metering system, current associated with electricity consumed by at least one load on the utility grid during a time interval (e.g., a first time interval). The metering system can obtain current data associated with the distributed electricity. In some cases, the metering system may obtain the current data from a data processing system or other metering systems (or metering devices).

At ACT 604, the metering system can determine at least one of a voltage harmonic metric, a current harmonic metric, and a power metric associated with the electricity delivered over the utility grid in the first time interval based on the voltage or the current detected by the sensor. The voltage harmonic metric can include one or more voltage harmonics. The current harmonic metric can include one or more current harmonics. The power metric can include one or more instantaneous powers. In some cases, the power metric can include one or more RMS values of the power obtained during the first time interval.

At ACT 606, the metering system can input at least one of the voltage harmonic metric, the current harmonic metric, and the power metric (e.g., the metrics or harmonics and power dataset) into a model trained with machine learning and deployed on the metering system. The model can be used to determine a likelihood that at least a portion of the electricity (e.g., a portion of the current data) delivered over the utility grid in the first time interval is used to charge an EV. In some cases, the metering system can receive or obtain the model from the data processing system remote from the metering system (or other remote computing devices configured to train the model). The data processing system can train the model via machine learning.

The model can be trained with first training data sampled at a first resolution and second training data sampled at a second resolution that is greater than the first resolution. For example, the first training data can include historical load metrics (e.g., residential load data) for various timestamps. The timestamps of the first training data can be associated or assigned with one of the first label or the second label. The first label can indicate EV charging, such as label ‘1’. The second label can indicate no EV charging during the corresponding timestamps, such as label ‘0’. The first training data can be sampled at or downsampled to a medium resolution, such as 1 Hz or other predetermined resolution. The second training data can include historical metrics generated by the metering system, such as a historical harmonics and power dataset. The historical metrics can be generated based on the current data detected by the sensor at the second resolution, such as 10 kHz, 1 kHz, or other resolutions according to the capability of the metering system or the metering device.

To use the training data for training the model, the metering system or the data processing system can apply one or more filters to the training data. For example, the data processing system can be configured to receive time-series data (e.g., residential load data) sampled at the first resolution corresponding to the residential electric load. The data processing system can detect, based on a second threshold, one or more time intervals of EV charging in the time-series data. These time intervals can be predetermined (or historically determined) based on historical residential load data or simulated residential load data, for example. The data processing system can generate labels to be applied to the time-series data based on the detection of the one or more EV charging time intervals to indicate one or more time intervals of EV charging or no EV charging to generate the labeled data (e.g., labeled time-series data).

After generating the labeled data, the data processing system can receive a harmonics and power dataset sampled at the second resolution greater than the first resolution. The data processing system can input the labeled data and the harmonics and power data set into the SVM to train the SVM to classify the harmonics and power dataset to indicate EV charging or no EV charging. The data processing system can perform the classification on the harmonics and power dataset based on the labeled data including an indication of EV charging at certain time intervals and an indication of no EV charging at other time intervals. For instance, the data processing system can correlate the timestamps associated with the harmonics and power dataset to the labeled timestamps of the labeled data.

Responsive to training the SVM, the data processing system can use the trained SVM to filter (or obtain) a second harmonics and power dataset to generate a filtered second harmonics and power dataset (e.g., sometimes referred to generally as filtered data). The second harmonics and power dataset to be filtered can correspond to training data for the model. The filtering of the second harmonics and power dataset or the training data can be performed by the data processing system or the metering system.

For example, the metering system (or the data processing system) may filter the training data (e.g., second harmonics and power dataset) based on a comparison of an output of the SVM (e.g., the model or one of the models) trained to classify a harmonics and power data set as corresponding to EV charging or no EV charging with a second threshold. In this case, the second threshold may include an upper threshold or limit (e.g., 1.1) associated with the label ‘1’ and a lower threshold or limit (e.g., −0.1) associated with the label ‘0’. The metering system can extract or use at least a portion of the training data associated with the SVM outputs that satisfy the upper threshold or lower threshold. For example, the metering system can determine that the SVM output satisfies the upper threshold based on the SVM output being greater than or equal to the upper threshold. In another example, the metering system can determine that the SVM output satisfies the lower threshold based on the SVM output being less than or equal to the lower threshold.

After filtering the second harmonics and power dataset (or the training data), the metering system can use the filtered data for training the model via one or more machine learning techniques, such as CNN and LSTM network. In this case, the model can include a CNN-LSTM model. In some cases, the metering system can receive an update to the model from the data processing system. For example, the metering system may receive the update including additional training data to re-train or generate an update to the model. In another example, the metering system may receive a new model trained by the data processing system, such as to update or replace the current or existing model stored on the metering system. The metering system may receive the update periodically or when initiated by the administrator of the data processing system.

At ACT 608, the metering system can determine the likelihood that the first time interval corresponds to a charging event. The likelihood can be based on the output from the model that processed the input data (e.g., the metrics). For example, the model can generate and output a value based on the similarities or differences between the characteristics of the metrics and the characteristics of the historical metrics indicative of EV charging or no EV charging. If the characteristics of the metrics are more similar to the characteristics of the metrics representing the EV charging (e.g., learned by the model), the model can output a value relatively closer to ‘1’. Otherwise, if the characteristics of the metrics are more similar to the characteristics of the metrics representing no EV charging, the model can output a value relatively closer to ‘0’.

At ACT 610, the metering system can determine whether the likelihood satisfies a threshold, indicating that the time interval is associated with an EV charging event. If the likelihood is greater than or equal to the threshold, the metering system can determine that there is likely an EV charging occurrence in the time interval. In some cases, the threshold can be determined according to the training targets for the SVM. For example, the SVM can be trained to a first value (e.g., around 1) for EV charging occurrence and a second value (e.g., around 0) for no EV charging. The threshold can be a third value between the first and second values, such as a midpoint between the first and second values. The confidence (e.g., confidence score) that there is likely an EV charging occurrence can increase as the likelihood (e.g., value) is closer to the first value (e.g., higher confidence that the determination or estimation is accurate), for example. In this case, the metering system can proceed to ACT 612. Otherwise, if the likelihood is less than the threshold, such as below 0.5, 0.6., etc., the metering system can determine that there is no EV charging (e.g., unlikely that there is an EV charging occurrence) in the time interval. The confidence that there is likely no EV charging occurrence in the time interval may increase as the likelihood is closer to the second value, for example. In this case, the metering system can return to ACT 602 to detect current for another time interval.

At ACT 612, the metering system can execute an action associated with the performance of the utility grid responsive to the likelihood satisfying the threshold. To execute the action, the metering system may provide an alert to the data processing system indicating that an EV charging occurrence is detected in the time interval. Responsive to receiving the indication, the data processing system can communicate with the one or more devices within the utility grid to manage the generation or allocation of electricity for residential homes during the EV charging event. For example, during the EV charging, the one or more devices of the utility grid may increase the electricity allocated for the residential home or increase the generation of electricity for the duration of the EV charging. In some other cases, the metering system may communicate to the one or more devices of the utility grid (e.g., send alerts or indications to the one or more devices) to initiate the action.

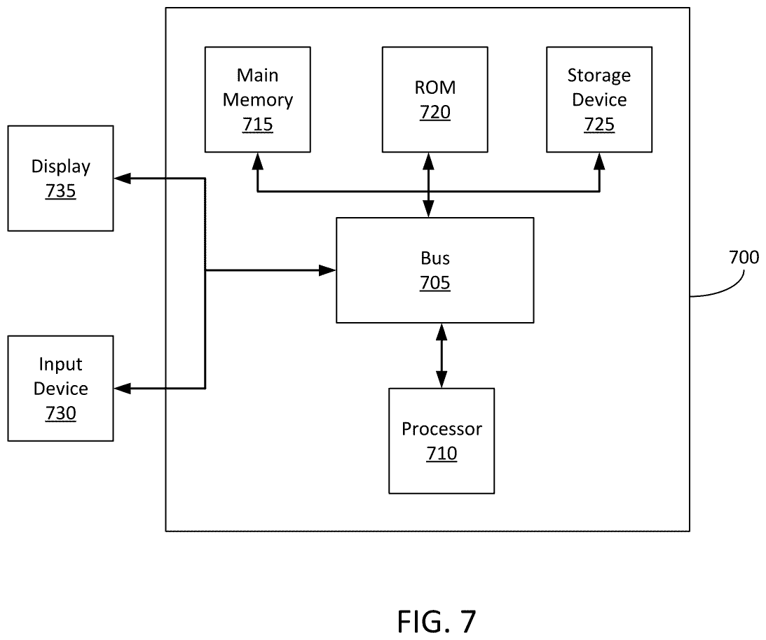

FIG. 7 is a block diagram of an example computer system 700. The computer system or computing device 700 can include or be used to implement the data processing system 150, the metering system 201, or its components. The computing system 700 includes at least one bus 705 or other communication component for communicating information and at least one processor 710 or processing circuit coupled to the bus 705 for processing information. The computing system 700 can also include one or more processors 710 or processing circuits coupled to the bus for processing information. The computing system 700 also includes at least one main memory 715, such as a random access memory (RAM) or other dynamic storage device, coupled to the bus 705 for storing information, and instructions to be executed by the processor 710. The main memory 715 can also be used for storing position information, utility grid data, command instructions, device status information, environmental information within or external to the utility grid, information on characteristics of electricity, or other information during execution of instructions by the processor 710. The computing system 700 may further include at least one read only memory (ROM) 720 or other static storage device coupled to the bus 705 for storing static information and instructions for the processor 710. A storage device 725, such as a solid state device, magnetic disk or optical disk, can be coupled to the bus 705 to persistently store information and instructions.

The computing system 700 may be coupled via the bus 705 to a display 735, such as a liquid crystal display, or active matrix display, for displaying information to a user such as an administrator of the data processing system or the utility grid. An input device 730, such as a keyboard or voice interface may be coupled to the bus 705 for communicating information and commands to the processor 710. The input device 730 can include a touch screen display 735. The input device 730 can also include a cursor control, such as a mouse, a trackball, or cursor direction keys, for communicating direction information and command selections to the processor 710 and for controlling cursor movement on the display 735. The display 735 can be part of the data processing system 150, or other components of FIGS. 1-2, among others.

The processes, systems, and methods described herein can be implemented by the computing system 700 in response to the processor 710 executing an arrangement of instructions contained in main memory 715. Such instructions can be read into main memory 715 from another computer-readable medium, such as the storage device 725. Execution of the arrangement of instructions contained in main memory 715 causes the computing system 700 to perform the illustrative processes described herein. One or more processors in a multi-processing arrangement may also be employed to execute the instructions contained in main memory 715. Hard-wired circuitry can be used in place of or in combination with software instructions together with the systems and methods described herein. Systems and methods described herein are not limited to any specific combination of hardware circuitry and software.

Although an example computing system has been described in FIG. 7, the subject matter including the operations described in this specification can be implemented in other types of digital electronic circuitry, or in computer software, firmware, or hardware, including the structures disclosed in this specification and their structural equivalents, or in combinations of one or more of them.

### Further Examples

The following examples pertain to further embodiments, from which numerous permutations and configurations will be apparent.

Example 1 includes a system, comprising: a metering system, comprising one or more processors and memory, located on a utility grid downstream from a substation to: detect, via a sensor of the metering system, current associated with electricity consumed in the utility grid during a first time interval; determine, based on the current detected by the sensor, a current harmonic metric and a power metric associated with the electricity delivered over the utility grid in the first time interval; input the current harmonic metric and the power metric into a model trained with machine learning and deployed on the metering system to determine a likelihood that at least a portion of the electricity delivered over the utility grid in the first time interval is used to charge an electric vehicle; and execute an action associated with performance of the utility grid responsive to the likelihood satisfying a threshold.

Example 2 includes the subject matter of Example 1, comprising: the metering system to receive, via a network, the model from a data processing system remote from the metering system, wherein the data processing system trains the model via machine learning.

Example 3 includes the subject matter of any of Examples 1 and 2, wherein the model is trained with first training data sampled at a first resolution and second training data sampled at a second resolution that is greater than the first resolution.

Example 4 includes the subject matter of any of Examples 1 through 3, wherein the model is trained with first training data comprising historical load metrics for a plurality of time stamps, wherein each of the plurality of time stamps is assigned one of a first label that indicates electric vehicle charging or a second label that indicates no electric vehicle charging during the corresponding plurality of time stamps.

Example 5 includes the subject matter of any of Examples 1 through 4, wherein training data used to train the model is filtered based on a comparison of an output of a support vector machine trained to classify a harmonics and power data set as corresponding to electric vehicle charging or no electric vehicle charging with a second threshold.

Example 6 includes the subject matter of any of Examples 1 through 5, wherein the model comprises a convolution neural network long short-term memory network.

Example 7 includes the subject matter of any of Examples 1 through 6, comprising: a data processing system comprising one or more processors coupled with memory, the data processing system to: receive time-series data sampled at a first resolution corresponding to residential electric load; detect, based on a second threshold, one or more time intervals of electric vehicle charging in the time-series data; label, based on the detection, the time-series data to indicate the one or more time intervals of electric vehicle charging to generate labeled time-series data; receive a harmonics and power data set sampled at a second resolution greater than the first resolution; input the labeled time-series data and the harmonics and power data set into a support vector machine to train the support vector machine to classify the harmonics and power data set to indicate electric vehicle charging or no electric vehicle charging; use the trained support vector machine to filter a second harmonics and power data set to generate a filtered second harmonics and power data set; and train, via a convolution neural network long short-term memory network, the model with the filtered second harmonics and power data set.

Example 8 includes the subject matter of any of Examples 1 through 7, wherein the first resolution corresponds to 1 Hz, the second resolution corresponds to 10 kHz, and the current detected by the sensor of the metering system is sampled at 10 KHz.

Example 9 includes the subject matter of any of Examples 1 through 8, comprising: the metering system to receive, via a network, an update to the model from a data processing system that re-trains the model based on additional data to generate the update to the model.

Example 10 includes the subject matter of any of Examples 1 through 9, comprising: the metering system, to execute the action, provides an alert to a data processing system indicating electric vehicle charging in the first time interval.

Example 11 includes a method, comprising: detecting, by a metering system comprising one or more processors and memory located on a utility grid downstream from a substation, via a sensor of the metering system, current associated with electricity consumed in the utility grid during a first time interval; determining, by the metering system, based on the current detected by the sensor, a current harmonic metric and a power metric associated with the electricity delivered over the utility grid in the first time interval; inputting, by the metering system, the current harmonic metric and the power metric into a model trained with machine learning and deployed on the metering system to determine a likelihood that at least a portion of the electricity delivered over the utility grid in the first time interval is used to charge an electric vehicle; and executing, by the metering system, an action associated with performance of the utility grid responsive to the likelihood satisfying a threshold.

Example 12 includes the subject matter of Example 11, comprising: receiving, by the metering system via a network, the model from a data processing system remote from the metering system, wherein the data processing system trains the model via machine learning.

Example 13 includes the subject matter of any of Examples 11 and 12, wherein the model is trained with first training data sampled at a first resolution and second training data sampled at a second resolution that is greater than the first resolution.

Example 14 includes the subject matter of any of Examples 11 through 13, wherein the model is trained with first training data comprising historical load metrics for a plurality of time stamps, wherein each of the plurality of time stamps is assigned one of a first label that indicates electric vehicle charging or a second label that indicates no electric vehicle charging during the corresponding plurality of time stamps.

Example 15 includes the subject matter of any of Examples 11 through 14, wherein training data used to train the model is filtered based on a comparison of an output of a support vector machine trained to classify a harmonics and power data set as corresponding to electric vehicle charging or no electric vehicle charging with a second threshold.

Example 16 includes the subject matter of any of Examples 11 through 15, wherein the model comprises a convolution neural network long short-term memory network.

Example 17 includes the subject matter of any of Examples 11 through 16, comprising: receiving, by a data processing system comprising one or more processors coupled with memory, time-series data sampled at a first resolution corresponding to residential electric load; detecting, by the data processing system based on a second threshold, one or more time intervals of electric vehicle charging in the time-series data; labeling, by the data processing system based on the detection, the time-series data to indicate the one or more time intervals of electric vehicle charging to generate labeled time-series data; receiving, by the data processing system, a harmonics and power data set sampled at a second resolution greater than the first resolution; inputting, by the data processing system, the labeled time-series data and the harmonics and power data set into a support vector machine to train the support vector machine to classify the harmonics and power data set to indicate electric vehicle charging or no electric vehicle charging; using, by the data processing system, the trained support vector machine to filter a second harmonics and power data set to generate a filtered second harmonics and power data set; and training, by the data processing system via a convolution neural network long short-term memory network, the model with the filtered second harmonics and power data set.

Example 18 includes the subject matter of any of Examples 11 through 17, comprising: receiving, by the metering system via a network, an update to the model from a data processing system that re-trains the model based on additional data to generate the update to the model.

Example 19 includes the subject matter of any of Examples 11 through 18, comprising: executing, by the metering system, the action to provide an alert to a data processing system indicating electric vehicle charging in the first time interval.

Example 20 includes a non-transitory computer-readable medium that stores processor-executable instructions that, when executed by one or more processors, cause the one or more processors to: detect, via a sensor of a metering system, current associated with electricity consumed in a utility grid during a first time interval; determine, based on the current detected by the sensor, a current harmonic metric and a power metric associated with the electricity delivered over the utility grid in the first time interval; input the current harmonic metric and the power metric into a model trained with machine learning and deployed on the metering system to determine a likelihood that at least a portion of the electricity delivered over the utility grid in the first time interval is used to charge an electric vehicle; and execute an action associated with performance of the utility grid responsive to the likelihood satisfying a threshold

Some of the descriptions herein emphasize the structural independence of the aspects of the system components (e.g., arbitration component) and illustrate one grouping of operations and responsibilities of these system components. Other groupings that execute similar overall operations are understood to be within the scope of the present application. Modules can be implemented in hardware or as computer instructions on a non-transient computer-readable storage medium, and modules can be distributed across various hardware- or computer-based components.

The systems described above can provide multiple ones of any or each of those components and these components can be provided on either a standalone system or on multiple instantiation in a distributed system. In addition, the systems and methods described above can be provided as one or more computer-readable programs or executable instructions embodied on or in one or more articles of manufacture. The article of manufacture can be cloud storage, a hard disk, a CD-ROM, a flash memory card, a PROM, a RAM, a ROM, or a magnetic tape. In general, the computer-readable programs can be implemented in any programming language, such as LISP, PERL, C, C++, C #, PROLOG, or in any byte code language such as JAVA. The software programs or executable instructions can be stored on or in one or more articles of manufacture as object code.

Example and non-limiting module implementation elements include sensors providing any value determined herein, sensors providing any value that is a precursor to a value determined herein, datalink or network hardware including communication chips, oscillating crystals, communication links, cables, twisted pair wiring, coaxial wiring, shielded wiring, transmitters, receivers, or transceivers, logic circuits, hard-wired logic circuits, reconfigurable logic circuits in a particular non-transient state configured according to the module specification, any actuator including at least an electrical, hydraulic, or pneumatic actuator, a solenoid, an op-amp, analog control elements (springs, filters, integrators, adders, dividers, gain elements), or digital control elements.

The subject matter and the operations described in this specification can be implemented in digital electronic circuitry, or in computer software, firmware, or hardware, including the structures disclosed in this specification and their structural equivalents, or in combinations of one or more of them. The subject matter described in this specification can be implemented as one or more computer programs, e.g., one or more circuits of computer program instructions, encoded on one or more computer storage media for execution by, or to control the operation of, data processing apparatuses. Alternatively or in addition, the program instructions can be encoded on an artificially generated propagated signal, e.g., a machine-generated electrical, optical, or electromagnetic signal that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. While a computer storage medium is not a propagated signal, a computer storage medium can be a source or destination of computer program instructions encoded in an artificially generated propagated signal. The computer storage medium can also be, or be included in, one or more separate components or media (e.g., multiple CDs, disks, or other storage devices include cloud storage). The operations described in this specification can be implemented as operations performed by a data processing apparatus on data stored on one or more computer-readable storage devices or received from other sources.

The terms “computing device”, “component” or “data processing apparatus” or the like encompass various apparatuses, devices, and machines for processing data, including by way of example a programmable processor, a computer, a system on a chip, or multiple ones, or combinations of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, app, script, or code) can be written in any form of programming language, including compiled or interpreted languages, declarative or procedural languages, and can be deployed in any form, including as a stand-alone program or as a module, component, subroutine, object, or other unit suitable for use in a computing environment. A computer program can correspond to a file in a file system. A computer program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform actions by operating on input data and generating output. The processes and logic flows can also be performed by, and apparatuses can also be implemented as, special purpose logic circuitry, e.g., an FPGA (field programmable gate array) or an ASIC (application specific integrated circuit). Devices suitable for storing computer program instructions and data can include non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The subject matter described herein can be implemented in a computing system that includes a back end component, e.g., as a data server, or that includes a middleware component, e.g., an application server, or that includes a front end component, e.g., a client computer having a graphical user interface or a web browser through which a user can interact with an implementation of the subject matter described in this specification, or a combination of one or more such back end, middleware, or front end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While operations are depicted in the drawings in a particular order, such operations are not required to be performed in the particular order shown or in sequential order, and all illustrated operations are not required to be performed. Actions described herein can be performed in a different order.

Having now described some illustrative implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features discussed in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation or embodiment, and references to “an implementation,” “some implementations,” “one implementation” or the like are not necessarily mutually exclusive and are intended to indicate that a particular feature, structure, or characteristic described in connection with the implementation may be included in at least one implementation or embodiment. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms. For example, a reference to “at least one of ‘A’ and ‘B’” can include only ‘A’, only ‘B’, as well as both ‘A’ and ‘B’. Such references used in conjunction with “comprising” or other open terminology can include additional items.

Where technical features in the drawings, detailed description or any claim are followed by reference signs, the reference signs have been included to increase the intelligibility of the drawings, detailed description, and claims. Accordingly, neither the reference signs nor their absence have any limiting effect on the scope of any claim elements.

Modifications of described elements and acts such as variations in sizes, dimensions, structures, shapes and proportions of the various elements, values of parameters, mounting arrangements, use of materials, colors, orientations can occur without materially departing from the teachings and advantages of the subject matter disclosed herein. For example, elements shown as integrally formed can be constructed of multiple parts or elements, the position of elements can be reversed or otherwise varied, and the nature or number of discrete elements or positions can be altered or varied. Other substitutions, modifications, changes and omissions can also be made in the design, operating conditions and arrangement of the disclosed elements and operations without departing from the scope of the present disclosure.

The systems and methods described herein may be embodied in other specific forms without departing from the characteristics thereof. Scope of the systems and methods described herein is thus indicated by the appended claims, rather than the foregoing description, and changes that come within the meaning and range of equivalency of the claims are embraced therein.

While this specification contains many specific implementation details, these should not be construed as limitations on the scope of any inventions or of what can be claimed, but rather as descriptions of features specific to particular embodiments of particular aspects. Certain features described in this specification in the context of separate embodiments can also be implemented in combination in a single embodiment. Conversely, various features described in the context of a single embodiment can also be implemented in multiple embodiments separately or in any suitable subcombination. Moreover, although features can be described above as acting in certain combinations and even initially claimed as such, one or more features from a claimed combination can in some cases be excised from the combination, and the claimed combination can be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing can be advantageous. Moreover, the separation of various system components in the embodiments described above should not be understood as requiring such separation in all embodiments, and it should be understood that the described program components and systems can generally be integrated in a single software product or packaged into multiple software products.

Thus, particular embodiments of the subject matter have been described. In some cases, the actions recited in the claims can be performed in a different order and still achieve desirable results. In addition, the processes depicted in the accompanying figures do not necessarily require the particular order shown, or sequential order, to achieve desirable results.

What is claimed is:

1. A system, comprising:
a metering system, comprising one or more processors and memory, located on a utility grid downstream from a substation to:
detect, via a sensor of the metering system, current associated with electricity consumed in the utility grid during a first time interval;
determine, based on the current detected by the sensor, a current harmonic metric and a power metric associated with the electricity delivered over the utility grid in the first time interval;
input the current harmonic metric and the power metric into a model trained with machine learning and deployed on the metering system to determine a likelihood that at least a portion of the electricity delivered over the utility grid in the first time interval is used to charge an electric vehicle; and
execute an action associated with performance of the utility grid responsive to the likelihood satisfying a threshold.

2. The system of claim 1, comprising:
the metering system to receive, via a network, the model from a data processing system remote from the metering system, wherein the data processing system trains the model via machine learning.

3. The system of claim 1, wherein the model is trained with first training data sampled at a first resolution and second training data sampled at a second resolution that is greater than the first resolution.

4. The system of claim 1, wherein the model is trained with first training data comprising historical load metrics for a plurality of time stamps, wherein each of the plurality of time stamps is assigned one of a first label that indicates electric vehicle charging or a second label that indicates no electric vehicle charging during the corresponding plurality of time stamps.

5. The system of claim 1, wherein training data used to train the model is filtered based on a comparison of an output of a support vector machine trained to classify a harmonics and power data set as corresponding to electric vehicle charging or no electric vehicle charging with a second threshold.

6. The system of claim 1, wherein the model comprises a convolution neural network long short-term memory network.

7. The system of claim 1, comprising:
a data processing system comprising one or more processors coupled with memory, the data processing system to:
receive time-series data sampled at a first resolution corresponding to residential electric load;
detect, based on a second threshold, one or more time intervals of electric vehicle charging in the time-series data;
label, based on the detection, the time-series data to indicate the one or more time intervals of electric vehicle charging to generate labeled time-series data;
receive a harmonics and power data set sampled at a second resolution greater than the first resolution;
input the labeled time-series data and the harmonics and power data set into a support vector machine to train the support vector machine to classify the harmonics and power data set to indicate electric vehicle charging or no electric vehicle charging;
use the trained support vector machine to filter a second harmonics and power data set to generate a filtered second harmonics and power data set; and
train, via a convolution neural network long short-term memory network, the model with the filtered second harmonics and power data set.

8. The system of claim 7, wherein the first resolution corresponds to 1 Hz, the second resolution corresponds to 10 kHz, and the current detected by the sensor of the metering system is sampled at 10 KHz.

9. The system of claim 1, comprising:
the metering system to receive, via a network, an update to the model from a data processing system that re-trains the model based on additional data to generate the update to the model.

10. The system of claim 1, comprising:
the metering system, to execute the action, provides an alert to a data processing system indicating electric vehicle charging in the first time interval.

11. A method, comprising:
detecting, by a metering system comprising one or more processors and memory located on a utility grid downstream from a substation, via a sensor of the metering system, current associated with electricity consumed in the utility grid during a first time interval;
determining, by the metering system, based on the current detected by the sensor, a current harmonic metric and a power metric associated with the electricity delivered over the utility grid in the first time interval;
inputting, by the metering system, the current harmonic metric and the power metric into a model trained with machine learning and deployed on the metering system to determine a likelihood that at least a portion of the electricity delivered over the utility grid in the first time interval is used to charge an electric vehicle; and
executing, by the metering system, an action associated with performance of the utility grid responsive to the likelihood satisfying a threshold.

12. The method of claim 11, comprising:
receiving, by the metering system via a network, the model from a data processing system remote from the metering system, wherein the data processing system trains the model via machine learning.

13. The method of claim 11, wherein the model is trained with first training data sampled at a first resolution and second training data sampled at a second resolution that is greater than the first resolution.

14. The method of claim 11, wherein the model is trained with first training data comprising historical load metrics for a plurality of time stamps, wherein each of the plurality of time stamps is assigned one of a first label that indicates electric vehicle charging or a second label that indicates no electric vehicle charging during the corresponding plurality of time stamps.

15. The method of claim 11, wherein training data used to train the model is filtered based on a comparison of an output of a support vector machine trained to classify a harmonics and power data set as corresponding to electric vehicle charging or no electric vehicle charging with a second threshold.

16. The method of claim 11, wherein the model comprises a convolution neural network long short-term memory network.

17. The method of claim 11, comprising:
receiving, by a data processing system comprising one or more processors coupled with memory, time-series data sampled at a first resolution corresponding to residential electric load;
detecting, by the data processing system based on a second threshold, one or more time intervals of electric vehicle charging in the time-series data;
labeling, by the data processing system based on the detection, the time-series data to indicate the one or more time intervals of electric vehicle charging to generate labeled time-series data;
receiving, by the data processing system, a harmonics and power data set sampled at a second resolution greater than the first resolution;
inputting, by the data processing system, the labeled time-series data and the harmonics and power data set into a support vector machine to train the support vector machine to classify the harmonics and power data set to indicate electric vehicle charging or no electric vehicle charging;
using, by the data processing system, the trained support vector machine to filter a second harmonics and power data set to generate a filtered second harmonics and power data set; and
training, by the data processing system via a convolution neural network long short-term memory network, the model with the filtered second harmonics and power data set.

18. The method of claim 11, comprising:
receiving, by the metering system via a network, an update to the model from a data processing system that re-trains the model based on additional data to generate the update to the model.

19. The method of claim 11, comprising:
executing, by the metering system, the action to provide an alert to a data processing system indicating electric vehicle charging in the first time interval.

20. A non-transitory computer-readable medium that stores processor-executable instructions that, when executed by one or more processors, cause the one or more processors to:
detect, via a sensor of a metering system, current associated with electricity consumed in a utility grid during a first time interval;
determine, based on the current detected by the sensor, a current harmonic metric and a power metric associated with the electricity delivered over the utility grid in the first time interval;
input the current harmonic metric and the power metric into a model trained with machine learning and deployed on the metering system to determine a likelihood that at least a portion of the electricity delivered over the utility grid in the first time interval is used to charge an electric vehicle; and
execute an action associated with performance of the utility grid responsive to the likelihood satisfying a threshold.
